(19) United States
(12) Patent Application Publication
(10) Pub. No.: US 2025/0107098 A1
(43) Pub. Date: Mar. 27, 2025

(54) SEMICONDUCTOR DEVICES AND ELECTRONIC SYSTEMS INCLUDING THE SAME

(71) Applicant: Samsung Electronics Co., Ltd., Suwon-si (KR)

(72) Inventors: Kohji Kanamori, Suwon-si (KR); Jae-Bok Baek, Suwon-si (KR); Donghyuck Jang, Suwon-si (KR); Jeehoon Han, Suwon-si (KR)

(21) Appl. No.: 18/807,157

(22) Filed: Aug. 16, 2024

(30) Foreign Application Priority Data
Sep. 22, 2023 (KR) 10-2023-0127090

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

Disclosed are semiconductor devices and electronic systems. The semiconductor device comprises a semiconductor substrate including first and second cell array regions and a connection region including a lower pad region and an upper pad region, a peripheral circuit structure including peripheral circuits on the semiconductor substrate, and a cell array structure on the peripheral circuit structure and including a first stack structure including first conductive patterns stacked on the peripheral circuit structure and a second stack structure including second conductive patterns stacked on the first stack structure. The first stack structure includes a connection portion that has a uniform thickness on the upper pad region, and first and second stepwise structures that are asymmetric with each other on the lower pad region. The second stack structure includes third and fourth stepwise structures that are symmetric with each other on the connection portion of the first stack structure.

### REFERENCE TO RELATED APPLICATION

This U.S. non-provisional application claims priority under 35 U.S.C. § 119 to Korean Patent Application No. 10-2023-0127090 filed on Sep. 22, 2023 in the Korean Intellectual Property Office, the disclosure of which is hereby incorporated by reference in its entirety.

### BACKGROUND

The present inventive concepts relate to semiconductor devices and electronic systems including the same.

Electronic systems that require data storage may need a semiconductor device capable of storing large amounts of data. Therefore, studies have been conducted to increase the data storage capacity of semiconductor devices. For example, as an approach to increase data storage capacity, semiconductor devices that include three-dimensionally arranged memory cells instead of two-dimensionally arranged memory cells have been proposed.

### SUMMARY

Some embodiments of the present inventive concepts provide semiconductor devices with improved reliability and increased integration.

Some embodiments of the present inventive concepts provide electronic systems including a semiconductor device.

The objects of the present inventive concepts are not limited to the above, and other objects which have not been mentioned above will be more clearly understood to those skilled in the art from the following description.

According to some embodiments of the present inventive concepts, a semiconductor device may include a semiconductor substrate that includes a first cell array region, a second cell array region, and a connection region between the first and second cell array regions, wherein the first and second cell array regions and the connection region are arranged in a first direction, and wherein the connection region includes a lower pad region and an upper pad region that are arranged in a second direction intersecting the first direction; a peripheral circuit structure that includes peripheral circuits on the semiconductor substrate; and a cell array structure on the peripheral circuit structure, wherein the cell array structure includes a first stack structure including a plurality of first conductive patterns stacked on the peripheral circuit structure and a second stack structure including a plurality of second conductive patterns stacked on the first stack structure. The first stack structure may include a connection portion that has a uniform thickness on the upper pad region; and first and second stepwise structures that are asymmetric with each other in the first direction on the lower pad region. The second stack structure may include third and fourth stepwise structures that are symmetric with each other in the first direction on the connection portion of the first stack structure.

According to some embodiments of the present inventive concepts, a semiconductor device may include a semiconductor substrate that includes a first cell array region, a second cell array region, and a connection region between the first and second cell array regions, wherein the first and second cell array regions and the connection region are arranged in a first direction, and wherein the connection region includes a lower pad region and an upper pad region that are arranged in a second direction intersecting the first direction; a peripheral circuit structure that includes pass transistors on the semiconductor substrate; and a cell array structure on the peripheral circuit structure. The cell array structure may include a first stack structure including a plurality of first conductive patterns stacked on a semiconductor layer, wherein the first stack structure includes a connection portion that has a uniform thickness on the upper pad region and first and second stepwise structures that are asymmetric with each other in the first direction on the lower pad region; and a second stack structure including a plurality of second conductive patterns stacked on the first stack structure, wherein the second stack structure includes third and fourth stepwise structures that are symmetric with each other in the first direction on the connection portion of the first stack structure. The pass transistors of the peripheral circuit structure may include first pass transistors that overlap the first stepwise structure of the first stack structure on the lower pad region; second pass transistors that overlap the second stepwise structure of the first stack structure on the lower pad region; and third pass transistors that overlap the third and fourth stepwise structures of the second stack structure on the upper pad region.

According to some embodiments of the present inventive concepts, an electronic system may include a semiconductor device; and a controller electrically connected through an input/output pad to the semiconductor device, the controller configured to control the semiconductor device. The semiconductor device may include a substrate that includes first and second cell array regions and a connection region between the first and second cell array regions; a first stack structure that includes a plurality of first conductive patterns stacked on the substrate; and a second stack structure that includes a plurality of second conductive patterns stacked on the first stack structure, wherein the first and second cell array regions and the connection region are arranged in a first direction, and wherein the connection region includes a lower pad region and an upper pad region that are arranged in a second direction intersecting the first direction. The first stack structure may include a connection portion that has a uniform thickness on the upper pad region; and first and second stepwise structures that are asymmetric with each other in the first direction on the lower pad region. The second stack structure may include third and fourth stepwise structures that are symmetric with each other in the first direction on the connection portion of the first stack structure.

Details of other example embodiments are included in the description and drawings.

### BRIEF DESCRIPTION OF THE DRAWINGS

FIG. 1 illustrates a block diagram showing a semiconductor device according to some embodiments of the present inventive concepts.

FIG. 2 illustrates a schematic diagram showing a row decoder, a pass transistor unit, and a memory block according to some embodiments of the present inventive concepts.

FIG. 3 illustrates a simplified circuit diagram showing a semiconductor device according to some embodiments of the present inventive concepts.

FIG. 4 illustrates a simplified conceptual diagram showing a semiconductor device according to some embodiments of the present inventive concepts.

FIG. 5 illustrates a plan view partially showing a semiconductor device according to some embodiments of the present inventive concepts.

FIGS. 6A, 6B, 6C, and 6D illustrate cross-sectional views respectively taken along lines A-A′, B-B′, C-C′, and D-D′ of FIG. 5, showing a semiconductor device according to some embodiments of the present inventive concepts.

FIG. 7 illustrates a simplified perspective view showing a stack structure of a semiconductor device according to some embodiments of the present inventive concepts.

FIGS. 8 and 9 illustrate perspective views showing a connection relationship between a stack structure and pass transistors in a semiconductor device according to some embodiments of the present inventive concepts.

FIGS. 10A and 10B illustrate cross-sectional views respectively taken along lines A-A′ and B-B′ of FIG. 5, showing a semiconductor device according to some embodiments of the present inventive concepts.

FIG. 11 illustrates a simplified cross-sectional view showing a cell array structure of a semiconductor device according to some embodiments of the present inventive concepts.

FIG. 12 illustrates a plan view partially showing a semiconductor device according to some embodiments of the present inventive concepts.

FIGS. 13A and 13B illustrate cross-sectional views respectively taken along lines A-A′ and B-B′ of FIG. 12, showing a semiconductor device according to some embodiments of the present inventive concepts.

FIGS. 14A, 15A, 16A, 17A, 18A, and 19A illustrate plan views showing a method of forming a stack structure in a semiconductor device according to some embodiments of the present inventive concepts.

FIGS. 14B, 15B, 16B, 17B, 18B, and 19B illustrate cross-sectional views taken along line A-A′ of FIGS. 14A, 15A, 16A, 17A, 18A, and 19A, respectively.

FIGS. 14C, 15C, 16C, 17C, 18C, and 19C illustrate cross-sectional views taken along line C-C′ of FIGS. 14A, 15A, 16A, 17A, 18A, and 19A, respectively.

FIG. 20 illustrates a simplified schematic diagram showing an electronic system that includes a semiconductor device according to some embodiments of the present inventive concepts.

FIG. 21 illustrates a simplified perspective view showing an electronic system that includes a semiconductor device according to some embodiments of the present inventive concepts.

FIGS. 22 and 23 illustrate simplified cross-sectional views showing a semiconductor package according to some embodiments of the present inventive concepts.

### DETAILED DESCRIPTION

With reference to the drawings, the following will describe in detail semiconductor devices and electronic systems including the same according to some example embodiments of the present inventive concepts.

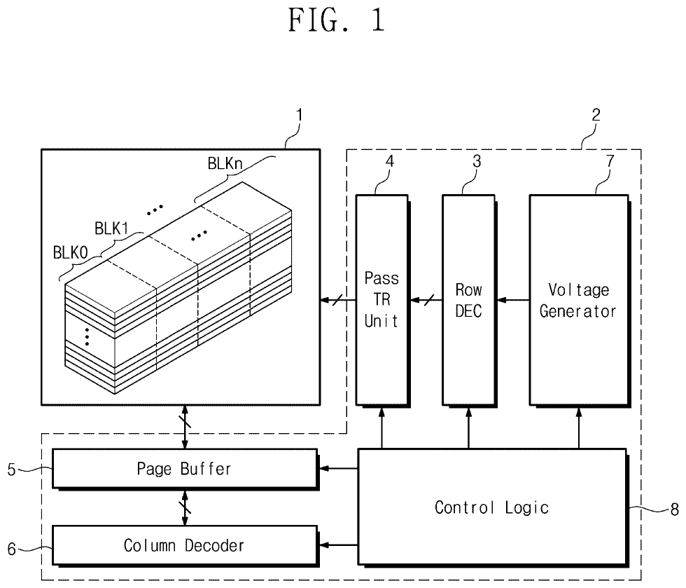

FIG. 1 illustrates a block diagram showing a semiconductor device according to some embodiments of the present inventive concepts.

Referring to FIG. 1, a semiconductor device may include a memory cell array 1 and a peripheral circuit 2 that controls the memory cell array 1. The peripheral circuit 2 may include a row decoder 3, a pass transistor unit 4, a page buffer 5, a column decoder 6, a voltage generator 7, and control circuits 8 (also referred to as control logic circuits).

The memory cell array 1 may include a plurality of memory blocks BLK0 to BLKn. Each of the memory blocks BLK0 to BLKn may include three-dimensionally arranged memory cells. For example, each of the memory blocks BLK0 to BLKn may include structures that are stacked along a third direction D3 on a plane elongated along first and second directions D1 and D2 that intersect each other. In response to a related block selection signal, the memory blocks BLK0 to BLKn may read data from or write data to a selected memory block.

In some embodiments, the semiconductor device may be, for example, a vertical NAND Flash memory device. In the vertical NAND Flash memory device, the memory blocks BLK0 to BLKn may include a plurality of cell strings each being a NAND type.

In some embodiments, the semiconductor device may be a variable resistance memory device. In the variable resistance memory device, the memory blocks BLK0 to BLKn may include memory cells that are correspondingly disposed at intersections between word lines and bit lines. In this description, each of the memory cells may include a resistive memory element. The resistive memory element may include, for example, perovskite compounds, transition metal oxide, phase-change materials, magnetic materials, ferromagnetic materials, or anti-ferromagnetic materials.

The row decoder 3 may decode an externally input address to select one of word lines included in the memory blocks BLK0 to BLKn.

In accordance with a block selection signal, the pass transistor unit 4 may connect the row decoder 3 to one selected from the memory blocks BLK0 to BLKn. The pass transistor unit 4 may include a plurality of pass transistors, which pass transistors may be correspondingly connected to ends of word lines included in each of the memory blocks BLK0 to BLKn. As used herein, “an element A connected to an element B” (or similar language) means that the element A is physically and/or electrically connected to the element B.

The page buffer 5 may be connected through bit lines to the memory cell array 1 and may read data stored in the memory cells.

The column decoder 6 may decode the externally input address to select one of bit lines. The column decoder 6 may provide a data transmission path between the page buffer 5 and an external device (e.g., a memory controller).

The control circuit 8 may control the voltage generator 7 to generate voltages (e.g., program voltage, read voltage, and erase voltage) required for internal operations of the memory cell array 1.

Based on a command signal, an address signal, and a control signal, the control circuit 8 may generate various control signals to program data to the memory cell array 1, to read data from the memory cell array 1, or to erase data stored in the memory cell array 1.

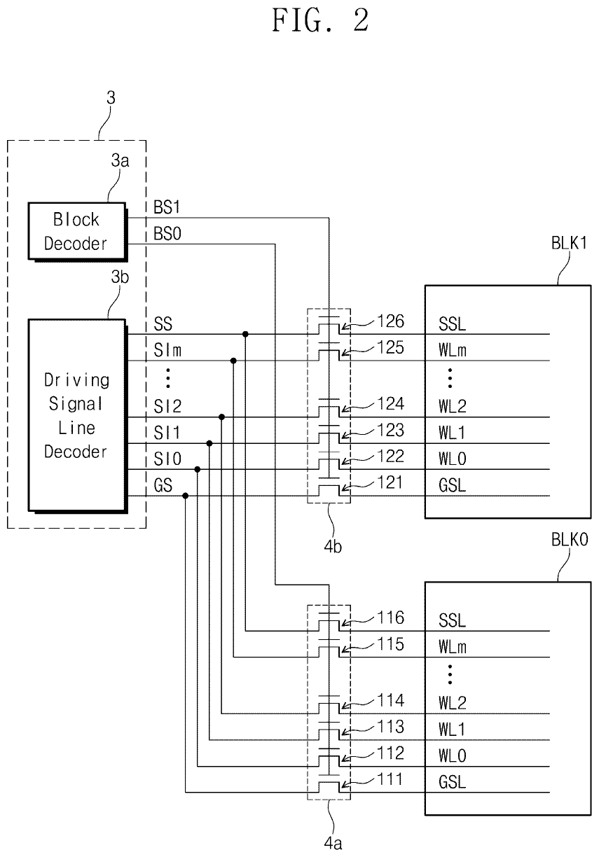

FIG. 2 illustrates a schematic diagram showing a row decoder, a pass transistor unit, and a memory block according to some embodiments of the present inventive concepts.

Referring to FIG. 2, first and second memory blocks BLK0 to BLK1 may be disposed adjacent to each other, and may each include a ground selection line GSL, a plurality of word lines WL0 to WLm where m is a positive integer, and a string selection line SSL.

The row decoder 3 may include a block decoder 3a and a driving signal line decoder 3b.

The pass transistor unit 4 may include a first pass transistor unit 4a that corresponds to the first memory block BLK0 and a second pass transistor unit 4b that corresponds to the second memory block BLK1. The first pass transistor unit 4a may include a plurality of pass transistors 111 to 116, and the second pass transistor unit 4b may include a plurality of pass transistors 121 to 126.

The block decoder 3a may be connected through a first block selection signal line BS0 to the first pass transistor unit 4a and through a second block selection signal line BS1 to the second pass transistor unit 4b.

The first block selection signal line BS0 may be connected to gates of the plurality of pass transistors 111 to 116. For example, when a first block selection signal is activated which is provided through the first block selection signal line BS0, the plurality of pass transistors 111 to 116 may be turned on and thus the first memory block BLK0 may be selected. In addition, the second block selection signal line BS1 may be connected to gates of the plurality of pass transistors 121 to 126. For example, when a second block selection signal is activated which is provided through the second block selection signal line BS1, the plurality of pass transistors 121 to 126 may be turned on and thus the second memory block BLK1 may be selected.

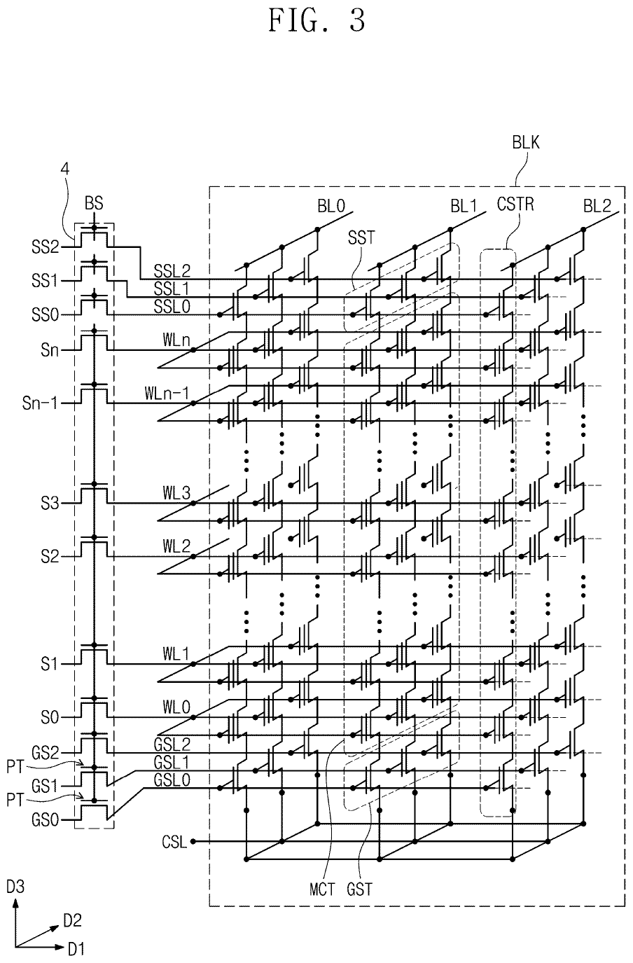

FIG. 3 illustrates a simplified circuit diagram showing a semiconductor device according to some embodiments of the present inventive concepts.

Referring to FIG. 3, in a semiconductor device according to some embodiments of the present inventive concepts, the pass transistor unit 4 may be connected to each memory block BLK.

Each memory block BLK may include a common source line CSL, a plurality of bit lines BL0 to BL2, and a plurality of cell strings CSTR disposed between the common source line CSL and the bit lines BL0 to BL2.

The cell strings CSTR may extend along a third direction D3 on a plane elongated along first and second directions D1 and D2. The cell strings CSTR may be two-dimensionally arranged along the first and second directions D1 and D2 that intersect each other.

The bit lines BL0 to BL2 may be spaced apart from each other in the first direction D1 and may extend in the second direction D2.

The plurality of cell strings CSTR may be connected in parallel to each of the bit lines BL0 to BL2. The plurality of cell strings CSTR may be connected in common to the common source line CSL. For example, the plurality of cell strings CSTR may be disposed between the plurality of bit lines BL0 to BL2 and one common source line CSL. A plurality of common source line CSL may be two-dimensionally arranged. The common source lines CSL may be supplied with the same voltage or may be electrically controlled independently of each other.

According to some embodiments, each of the cell strings CSTR may include a string selection transistor SST, memory cell transistors MCT connected in series to each other, and a ground selection transistor GST. Moreover, each of the memory cell transistors MCT may include a data storage element.

For example, in each of the cell strings CSTR, the string selection transistor SST may be coupled to the bit line BL0 to BL2, and the ground selection transistor GST may be coupled to the common source line CSL. The memory cell transistors MCT may be connected in series between the string selection transistor SST and the ground selection transistor GST.

According to some embodiments, the string selection transistor SST may be controlled by one of string selection lines SSL0 to SSL2, and the memory cell transistors MCT may be controlled by a plurality of word lines WL0 to WLn. In addition, the ground selection transistor GST may be controlled by a corresponding one of ground selection lines GSL0 to GLS2. The common source line CSL may be connected in common to sources of the ground selection transistors GST.

The memory cell transistors MCT may include gate electrodes, which are spaced apart at substantially the same distance from the common source lines CSL, connected in common to one of the word lines WL0 to WLn to thereby have the same potential state.

The ground selection lines GSL0 to GSL2 may be located at substantially the same level from the common source lines CSL and may be electrically separated from each other, and the same may be true of the string selection lines SSL0 to SSL2.

The word lines WL0 to WLn and the selection lines SSL0 to SSL2 and GSL0 to GSL2 of each memory block BLK may be connected to the pass transistor unit 4. The pass transistor unit 4 may include a plurality of pass transistors PT each connected to a corresponding one of the word lines WL0 to WLn and the selection lines SSL0 to SSL2 and GSL0 to GSL2.

The pass transistors PT of the pass transistor unit 4 may be controlled by a block selection signal BS provided from the row decoder 3. The pass transistors PT may provide driving signals GS0 to GS2, SS0 to SS2, and S0 to Sn to the word lines WL0 to WLn and the selection lines SSL0 to SSL2 and GSL0 to GLS2 included in a selected one of the memory blocks (see BLK0 to BLKn of FIG. 1). According to some embodiments, the word lines WL0 to WLn may be provided with a program voltage, a read voltage, a pass voltage, or a verification voltage, and the selection lines SSL0 to SSL2 and GSL0 to GSL2 may be provided with a ground voltage, a power voltage, or a threshold voltage.

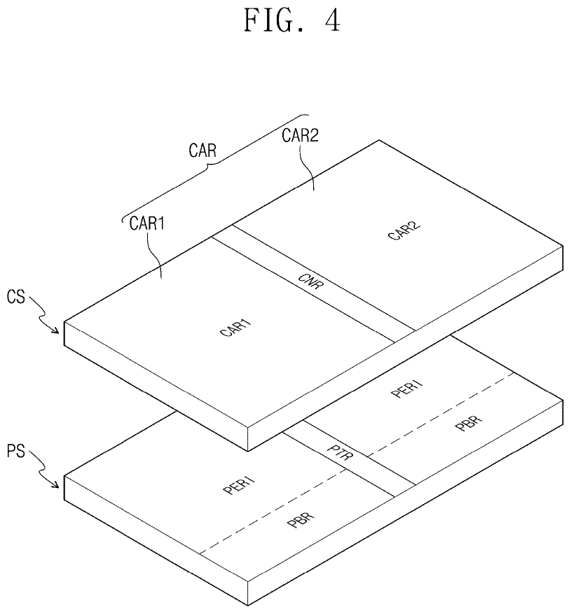

FIG. 4 illustrates a simplified conceptual diagram showing a semiconductor device according to some embodiments of the present inventive concepts.

Referring to FIG. 4, a semiconductor device according to some embodiments of the present inventive concepts may include a peripheral circuit structure PS and a cell array structure CS disposed on the peripheral circuit structure PS. When viewed in plan, the cell array structure CS may overlap the peripheral circuit structure PS. It will be understood that “an element A overlaps an element B” (or similar language) as used herein means that at least one line intersecting both the elements A and B exists. As the cell array structure CS is disposed on the peripheral circuit structure PS, there may be an increase in cell capacity per unit area of the semiconductor device according to the present inventive concepts.

According to some embodiments, the cell array structure CS may include a plurality of cell array regions CAR1 and CAR2 and a connection region CNR between the plurality of cell array regions CAR1 and CAR2. The plurality of cell array regions CAR1 and CAR2 may include the memory block BLK discussed with reference to FIG. 3.

The peripheral circuit structure PS may include a pass transistor region PTR, page buffer regions PBR, and peripheral circuit regions PERI. In some embodiments, the peripheral circuit structure PS may include a row decoder, a column decoder, a pass transistor unit, a page buffer, a voltage generator, and control circuits.

The pass transistor region PTR may be disposed between the page buffer regions PBR and between the peripheral circuit regions PERI. The pass transistor region PTR may include pass transistors. The pass transistor region PTR may overlap the connection region CNR of the cell array structure CS.

The page buffer regions PBR and the peripheral circuit regions PERI may overlap the cell array regions CAR1 and CAR2. The page buffer regions PBR may include page buffer circuits, and the peripheral circuit regions PER may include a voltage generator and control circuits.

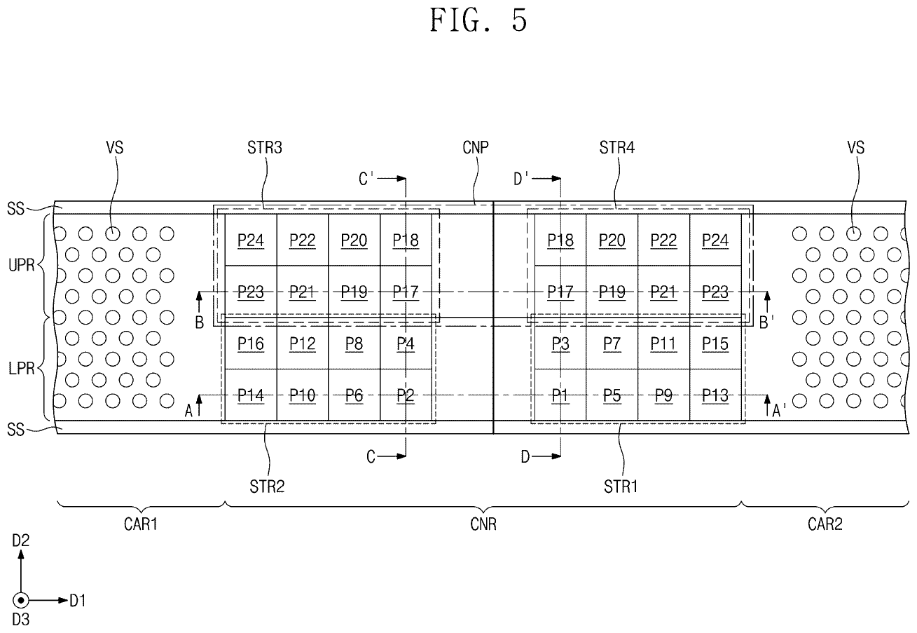

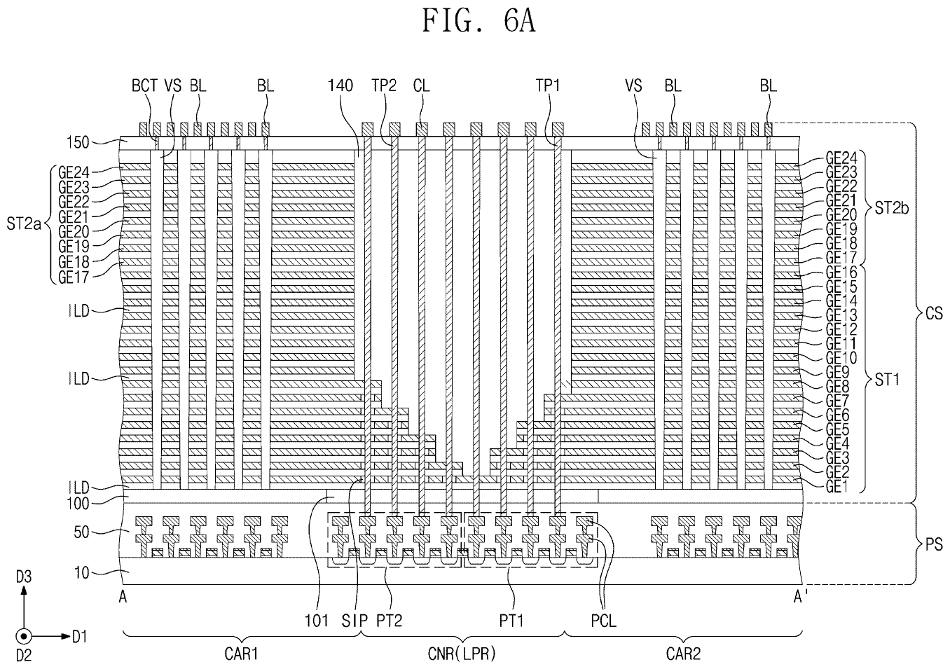

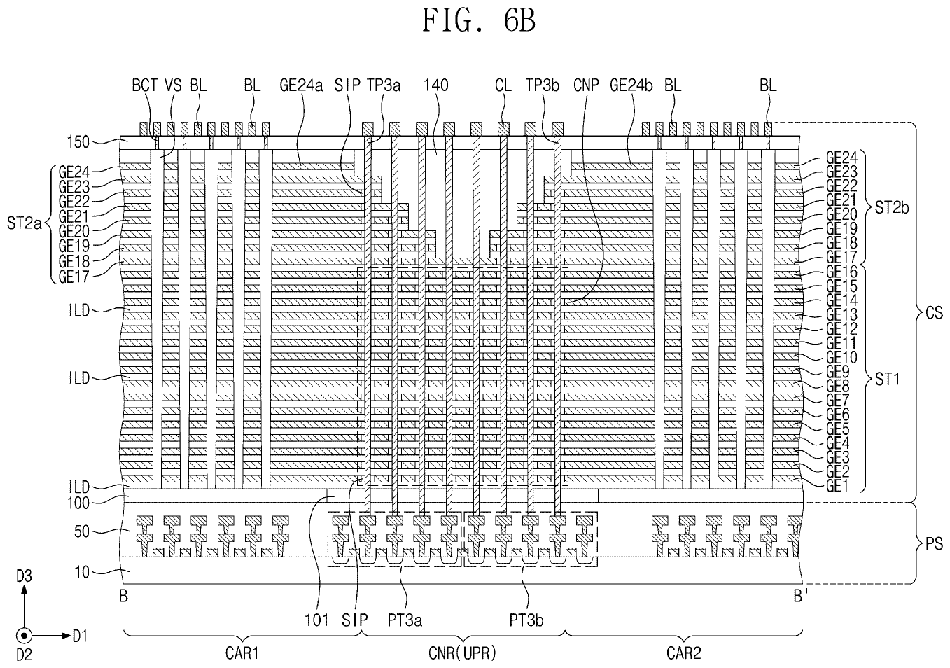

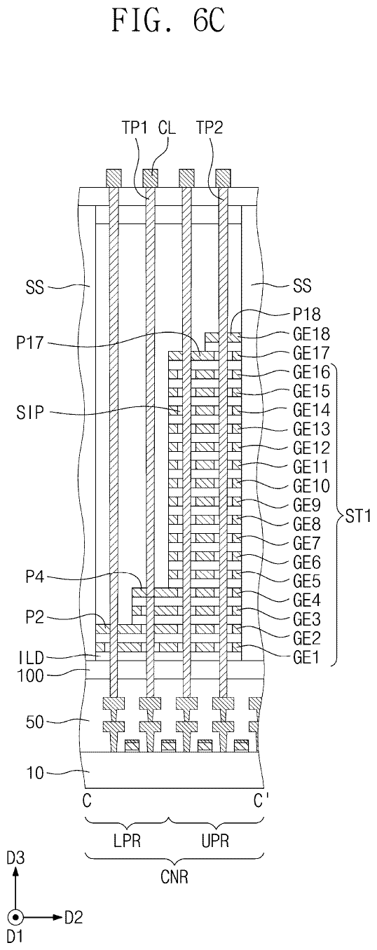

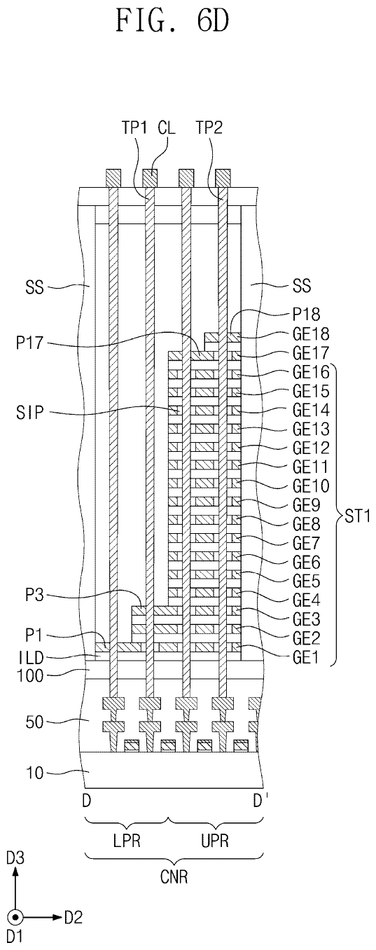

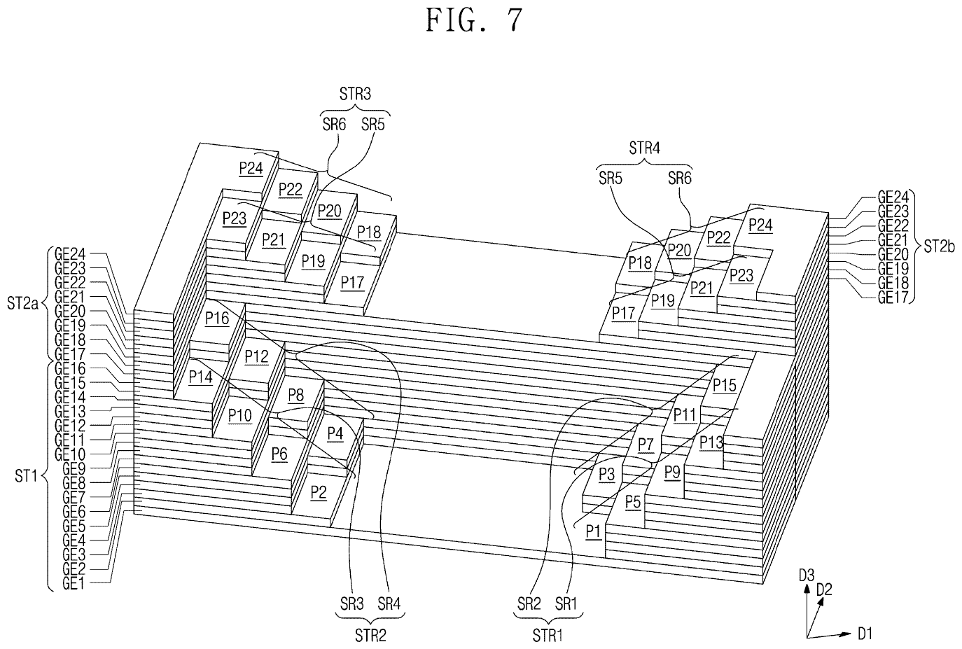

FIG. 5 illustrates a plan view partially showing a semiconductor device according to some embodiments of the present inventive concepts. FIGS. 6A, 6B, 6C, and 6D illustrate cross-sectional views respectively taken along lines A-A′, B-B′, C-C′, and D-D′ of FIG. 5, showing a semiconductor device according to some embodiments of the present inventive concepts. FIG. 7 illustrates a simplified perspective view showing a stack structure of a semiconductor device according to some embodiments of the present inventive concepts.

Referring to FIGS. 5, 6A, 6B, 6C, and 6D, a semiconductor device according to some embodiments of the present inventive concepts may include a semiconductor substrate 10, a peripheral circuit structure PS on the semiconductor substrate 10, and a cell array structure CS on the peripheral circuit structure PS.

The semiconductor substrate 10 may include a semiconductor material and may be, for example, a silicon substrate, a silicon-germanium substrate, a germanium substrate, or a monocrystalline epitaxial layer grown on a monocrystalline silicon substrate. The semiconductor substrate 10 may have a top surface, which is parallel to a first direction D1 and a second direction D2 that intersect each other and is perpendicular to a third direction D3. The first, second, and third directions D1, D2, and D3 may be directions orthogonal to each other.

The semiconductor substrate 10 may include first and second cell array regions CAR1 and CAR2 and a connection region CNR between the first and second cell array regions CAR1 and CAR2, when viewed in the first direction D1. The connection CNR may include a lower pad region LPR and an upper pad region UPR disposed in the second direction D2 that intersects the first direction D1 and is parallel to the top surface of the semiconductor substrate 10. In some embodiments, the first and second cell array regions CAR1 and CAR2 may be the peripheral circuit regions PERI and the page buffer regions PBR discussed with reference to FIG. 4.

A first pass transistor circuit PT1 and a second pass transistor circuit PT2 may be provided on the semiconductor substrate 10 of the lower pad region LPR, and third pass transistor circuits PT3a and PT3b may be provided on the semiconductor substrate 10 of the upper pad region UPR.

The semiconductor substrate 10 of the first and second cell array regions CAR1 and CAR2 may be distributively provided thereon with page buffer circuits connected to bit lines BL and with peripheral circuits that control the first, second, and third pass transistor circuits PT1, PT2, PT3a, and PT3b.

A lower dielectric layer 50 may be provided on a front surface of the semiconductor substrate 10. On the semiconductor substrate 10, the lower dielectric layer 50 may cover or overlap the pass transistor circuits PT1, PT2, PT3a, and PT3b, the page buffer circuits, the peripheral circuits, and peripheral circuit lines PCL. The peripheral circuit lines PCL may be electrically connected to the peripheral circuits.

The lower dielectric layer 50 may include a plurality of stacked dielectric layers. For example, the lower dielectric layer 50 may include one or more of a silicon oxide layer, a silicon nitride layer, a silicon oxynitride layer, or a low-k dielectric layer.

The cell array structure CS may be disposed on the lower dielectric layer 50, and may include a semiconductor layer 100, a stack structure ST1, ST2a, and ST2b, vertical structures VS, bit lines BL, connection lines CL, and through plugs TP1, TP2, TP3a, and TP3b.

The semiconductor layer 100 may be disposed on a top surface of the lower dielectric layer 50. The semiconductor layer 100 may have an opening on the connection region CNR, and the opening may be filled with a dielectric pattern 101. The dielectric pattern 101 may be in contact with the lower dielectric layer 50, and may have a top surface substantially coplanar with that of the semiconductor layer 100.

The stack structure ST1, ST2a, and ST2b may be disposed on the semiconductor layer 100. When viewed in plan, the stack structure ST1, ST2a, and ST2b may extend along the first direction D1 and may be disposed between separation structures SS that are spaced apart from each other in the second direction D2. When viewed in plan, the separation structures SS may extend in parallel along the first direction D1. The separation structures SS may include a dielectric material, such as silicon oxide. The separation structures SS may be in contact with the top surface of the semiconductor layer 100.

The stack structure ST1, ST2a, and ST2b may include conductive patterns GE1 to GE24 and interlayer dielectric layers ILD that are alternately stacked along the third direction D3 (or a vertical direction).

The conductive patterns GE1 to GE24 may include, for example, at least one selected from doped semiconductors (e.g., doped silicon), metals (e.g., tungsten, copper, or aluminum), conductive metal nitrides (e.g., titanium nitride or tantalum nitride), or transition metals (e.g., titanium or tantalum). The dielectric layers ILD may include one or more of a silicon oxide layer or a low-k dielectric layer.

According to some embodiments, the semiconductor device may be a vertical NAND Flash memory device, and in this case, the conductive patterns GE1 to GE24 of the stack structure ST1, ST2a, and ST2b may be used as the ground selection lines GSL0, GSL1, and GSL2, the word lines WL0 to WLn, and the string selection lines SSL0, SSL1, and SSL2 discussed with reference to FIG. 3.

The conductive patterns GE1 to GE24 may be stacked on the semiconductor layer 100 to have stepwise structures STR1, STR2, STR3, and STR4 on the connection region CNR. The conductive patterns GE1 to GE24 may include pad portions P1 to P24 that define the stepwise structures STR1, STR2, STR3, and STR4 on the connection region CNR (e.g., see FIG. 5). The pad portions P1 to P24 of the conductive patterns GE1 to GE24 may be located at positions that are horizontally and vertically different from each other.

According to some embodiments, the stack structure ST1, ST2a, and ST2b may include a first stack structure ST1 that includes first conductive patterns GE1 to GE16 vertically stacked on the semiconductor layer 100, and may also include a second stack structure ST2a and ST2b that includes second conductive patterns GE17 to GE24 vertically stacked on the first stack structure ST1.

In the first stack structure ST1, each of the first conductive patterns GE1 to GE16 may be a single layer that continuously extends along the first direction D1. The first stack structure ST1 may include a first stepwise structure STR1 and a second stepwise structure STR2 on the lower pad region LPR. The first stack structure ST1 may include a connection portion CNP that has a uniform thickness (e.g., in the third direction D3) on the upper pad region UPR. As used herein, “an element A has a uniform thickness” (or similar language) means that the element A has a substantially uniform thickness in at least one direction. The first stepwise structure STR1 and the second stepwise structure STR2 may be adjacent in the second direction D2 to the connection portion CNP. The first stepwise structure STR1 and the second stepwise structure STR2 may be disposed asymmetrically with each other in the first direction D1 on the lower pad region LPR.

In the first stack structure ST1, the first stepwise structure STR1 may be defined by pad portions P1, P3, P5, P7, P9, P11, P13, and P15 of odd-numbered first conductive patterns GE1, GE3, GE5, GE7, GE9, GE11, GE13, and GE15. The odd-numbered first conductive patterns GE1, GE3, GE5, GE7, GE9, GE11, GE13, and GE15 may also be referred to herein as first ones of the first conductive patterns. In the first stack structure ST1, the second stepwise structure STR2 may be defined by pad portions P2, P4, P6, P8, P10, P12, P14, and P16 of even-numbered first conductive patterns GE2, GE4, GE6, GE8, GE10, GE12, GE14, and GE16. The even-numbered first conductive patterns GE2, GE4, GE6, GE8, GE10, GE12, GE14, and GE16 may also be referred to herein as second ones of the first conductive patterns. As used herein, it will be understood that the second ones of the first conductive patterns GE2, GE4, GE6, GE8, GE10, GE12, GE14, and GE16 are different from the first ones of the first conductive patterns GE1, GE3, GE5, GE7, GE9, GE11, GE13, and GE15. For example, the first ones of the first conductive patterns GE1, GE3, GE5, GE7, GE9, GE11, GE13, and GE15 may be alternately stacked with the second ones of the first conductive patterns GE2, GE4, GE6, GE8, GE10, GE12, GE14, and GE16 in the first stack structure ST1.

In each of the first and second stepwise structures STR1 and STR2, a step difference between stairs (i.e., steps) adjacent in the first direction D1 may be different from that between stairs (i.e., steps) adjacent in the second direction D2. In other words, in each of the first and second stepwise structures STR1 and STR2, a step difference between adjacent ones of the pad portions P1 to P16 in the first direction D1 may be different from a step difference between adjacent ones of the pad portions P1 to P16 in the second direction D2 (e.g., see FIG. 7). For example, each of the first and second stepwise structures STR1 and STR2 may increase by four steps along the first direction D1 and two steps along the second direction D2.

Referring to FIG. 7, the first stepwise structure STR1 may include a first portion SR1 defined by the first conductive patterns GE1, GE5, GE9, and GE13 positioned at first odd-numbered layers, and may also include a second portion SR2 defined by the first conductive patterns GE3, GE7, GE11, and GE15 positioned at second odd-numbered layers. The second portion SR2 may be adjacent in the second direction D2 to the first portion SR1.

The second stepwise structure STR2 may include a third portion SR3 defined by the first conductive patterns GE2, GE6, GE10, and GE14 positioned at first even-numbered layers, and may also include a fourth portion SR4 defined by the first conductive patterns GE4, GE8, GE12, and GE16 positioned at second even-numbered layers. The fourth portion SR4 may be adjacent in the second direction D2 to the third portion SR3.

In the second stack structure ST2a and ST2b, each of the second conductive patterns GE17 to GE24 may include a first sub-pattern (also referred to herein as a first sub-conductive pattern) and a second sub-pattern (also referred to herein as a second sub-conductive pattern) that are horizontally spaced apart from each other.

The second stack structure ST2a and ST2b may include a first sub-stack structure ST2a and a second sub-stack structure ST2b that are spaced apart from each other in the first direction D1. The first sub-stack structure ST2a may include first sub-patterns of the second conductive patterns GE17 to GE24, and the second sub-stack structure ST2b may include second sub-patterns of the second conductive patterns GE17 to GE24.

The first sub-stack structure ST2a may include a third stepwise structure STR3, and the second sub-stack structure ST2b may include a fourth stepwise structure STR4 that is disposed mirror-symmetrically with the third stepwise structure STR3. The third and fourth stepwise structures STR3 and STR4 may be spaced apart from each other in the first direction D1 on the connection portion CNP of the first stack structure ST1. The third and fourth stepwise structures STR3 and STR4 may be located at a vertical level higher than that of the first and second stepwise structures STR1 and STR2 of the first stack structure ST1. As used herein, the term “vertical level” means a height in a vertical direction (third direction D3) from an upper surface (front surface) of the semiconductor substrate 10.

The third stepwise structure STR3 may be defined by pad portions P17 to P24 of the first sub-patterns of the second conductive patterns GE17 to GE24. The fourth stepwise structure STR4 may be defined by pad portions P17 to P24 of the second sub-patterns of the second conductive patterns GE17 to GE24. For example, a step difference between steps in the first direction D1 in each of the first and second stepwise structures STR1 and STR2 may be different from a step difference between steps in the first direction D1 in each of the third and fourth stepwise structures STR3 and STR4. In other words, a step difference between adjacent ones of the pad portions P1 to P16 in the first direction D1 in each of the first and second stepwise structures STR1 and STR2 may be different from a step difference between adjacent ones of the pad portions P17 to P24 in the first direction D1 in each of the third and fourth stepwise structures STR3 and STR4. For example, each of the first and second stepwise structures STR1 and STR2 may increase by four steps along the first direction D1, and each of the third and fourth stepwise structures STR3 and STR4 may increase by two steps along the first direction D1. For example, each of the third and fourth stepwise structures STR3 and STR4 may increase by one step along the second direction D2.

Referring still to FIG. 7, each of the third and fourth stepwise structures STR3 and STR4 may include a fifth portion SR5 defined by the second conductive patterns GE17, GE19, GE21, and GE23 positioned at odd-numbered layers, and may also include a sixth portion SR6 defined by the second conductive patterns GE18, GE20, GE22, and GE24 positioned on even-numbered layers. The sixth portion SR6 may be adjacent in the second direction D2 to the fifth portion SR5.

When viewed in plan, the first sub-pass transistor circuit PT3a may overlap the third stepwise structure STR3 of the second stack structure ST2a. When viewed in plan, the second sub-pass transistor circuit PT3b may overlap the fourth stepwise structure STR4 of the second stack structure ST2b (e.g., see FIG. 6B).

Referring back to FIGS. 5, 6A, 6B, 6C, and 6D, a plurality of vertical structures VS may penetrate (i.e., extend into) the first and second stack structures ST1, ST2a, and ST2b on each of the first and second cell array regions CAR1 and CAR2. When viewed in plan, the vertical structures VS may be arranged in a straight or zigzag fashion.

Each of the vertical structures VS may include a vertical semiconductor pattern and a data storage pattern that surrounds a sidewall of the vertical semiconductor pattern. The vertical semiconductor pattern may include a semiconductor material, such as silicon (Si), germanium (Ge), or a mixture thereof. The vertical semiconductor pattern including a semiconductor material may serve as channels of the string selection transistors SST, the memory cell transistors MCT, and the ground selection transistors GST discussed with reference to FIG. 3. The data storage pattern may be formed of a single thin layer or a plurality of thin layers. In some embodiments of the present inventive concepts, the data storage pattern may include a tunnel dielectric layer, a charge storage layer, and a blocking dielectric layer that are sequentially stacked on the sidewall of the vertical semiconductor pattern and are used as a data storage layer of a NAND Flash memory device. For example, the charge storage layer may be a trap dielectric layer, a floating gate electrode, or a dielectric layer including conductive nano-dots.

On each of the first and second cell array regions CAR1 and CAR2, the bit lines BL may extend in the second direction D2 while running across the stack structure ST1, ST2a, and ST2b. The bit lines BL may be electrically connected through bit-line contact plugs BCT to the vertical structures VS.

On the connection region CNR, a buried dielectric layer 140 may cover the first to fourth stepwise structures STR1 to STR4 of the stack structure ST1, ST2a, and ST2b. An interlayer dielectric layer 150 may be disposed on the buried dielectric layer 140 and may cover top surfaces of the vertical structures VS.

On the connection region CNR, first, second, and third through plugs TP1, TP2, TP3a, and TP3b may penetrate the interlayer dielectric layer 150 and the buried dielectric layer 140 to be coupled to the pad portions P1 to P24 of the first and second conductive patterns GE1 to GE24.

The first, second, and third through plugs TP1, TP2, TP3a, and TP3b may connect the pad portions P1 to P24 of the first and second conductive patterns GE1 to GE24 to their corresponding pass transistor circuits PT1, PT2, PT3a, and PT3b.

The first, second, and third through plugs TP1, TP2, TP3a, and TP3b may penetrate the dielectric pattern 101 to be coupled to the peripheral circuit lines PCL of the peripheral circuit structure PS. The first, second, and third through plugs TP1, TP2, TP3a, and TP3b may have substantially the same vertical length.

For example, on the lower pad region LPR, the first through plugs TP1 may penetrate the first stepwise structure STR1 of the first stack structure ST1. The first through plugs TP1 may electrically connect the odd-numbered first conductive patterns GE1, GE3, GE5, GE7, GE9, GE11, GE13, and GE15 that define the first stepwise structure STR1 to their corresponding pass transistors of the first pass transistor circuit PT1. The first through plugs TP1 may penetrate corresponding pad portions P1, P3, P5, P7, P9, P11, P13, and P15 of the first conductive patterns GE1, GE3, GE5, GE7, GE9, GE11, GE13, and GE15. When viewed in plan, the first pass transistor circuit PT1 may overlap the first stepwise structure STR1 of the first stack structure ST1.

The first through plugs TP1 may have their sidewalls in contact with corresponding first conductive patterns GE1, GE3, GE5, GE7, GE9, GE11, GE13, and GE15. Sidewall dielectric patterns SIP may be correspondingly interposed between the sidewalls of the first through plugs TP1 and the first conductive patterns GE1 to GE16 stacked below pad portions P1, P3, P5, P7, P9, P11, P13, and P15 of the first conductive patterns GE1, GE3, GE5, GE7, GE9, GE11, GE13, and GE15.

On the lower pad region LPR, the second through plugs TP2 may penetrate the second stepwise structure STR2 of the first stack structure ST1. The second through plugs TP2 may electrically connect the even-numbered first conductive patterns GE2, GE4, GE6, GE8, GE10, GE12, GE14, and GE16 that constitute the second stepwise structure STR2 to their corresponding pass transistors of the second pass transistor PT2. The second through plugs TP2 may penetrate corresponding pad portions P2, P4, P6, P8, P10, P12, P14, and P16 of the first conductive patterns GE2, GE4, GE6, GE8, GE10, GE12, GE14, and GE16. When viewed in plan, the second pass transistor circuit PT2 may overlap the second stepwise structure STR2 of the first stack structure ST1.

The second through plugs TP2 may have their sidewalls in contact with corresponding even-numbered first conductive patterns GE2, GE4, GE6, GE8, GE10, GE12, GE14, and GE16. Sidewall dielectric patterns SIP may be correspondingly interposed between the sidewalls of the second through plugs TP2 and the first conductive patterns GE1 to GE16 stacked below pad portions P2, P4, P6, P8, P10, P12, P14, and P16 of the first conductive patterns GE2, GE4, GE6, GE8, GE10, GE12, GE14, and GE16.

On the upper pad region UPR, the third through plugs TP3a and TP3b may penetrate the third and fourth stepwise structures STR3 and STR4 of the second stack structure ST2a and ST2b, and may also penetrate the connection portion CNP of the first stack structure ST1.

The third through plugs TP3a and TP3b may electrically connect the second conductive patterns GE17 to GE24 to their corresponding pass transistors of the third pass transistor circuits PT3a and PT3b. Ones TP3a of the third through plugs TP3a and TP3b may correspondingly penetrate the pad portions P17 to P24 of the second conductive patterns GE17 to GE24 of the first sub-stack structure ST2a. Others TP3b of the third through plugs TP3a and TP3b may correspondingly penetrate the pad portions P17 to P24 of the second conductive patterns GE17 to GE24 of the second sub-stack structure ST2b.

The second conductive patterns GE17 to GE24 of the first sub-stack structure ST2a may be connected through the third through plugs TP3a to the first sub-pass transistor circuit PT3a. The second conductive patterns GE17 to GE24 of the second sub-stack structure ST2b may be connected through the third through plugs TP3b to the second sub-pass transistor circuit PT3b.

Sidewall dielectric patterns SIP may be correspondingly interposed between the third through plugs TP3a and TP3b and the first and second conductive patterns GE1 to GE23 stacked below the pad portions P17 to P24 of the second conductive patterns GE17 to GE24.

On the connection region CNR, the connection lines CL may be disposed on the interlayer dielectric layer 150 and coupled to the first, second, and third through plugs TP1, TP2, TP3a, and TP3b.

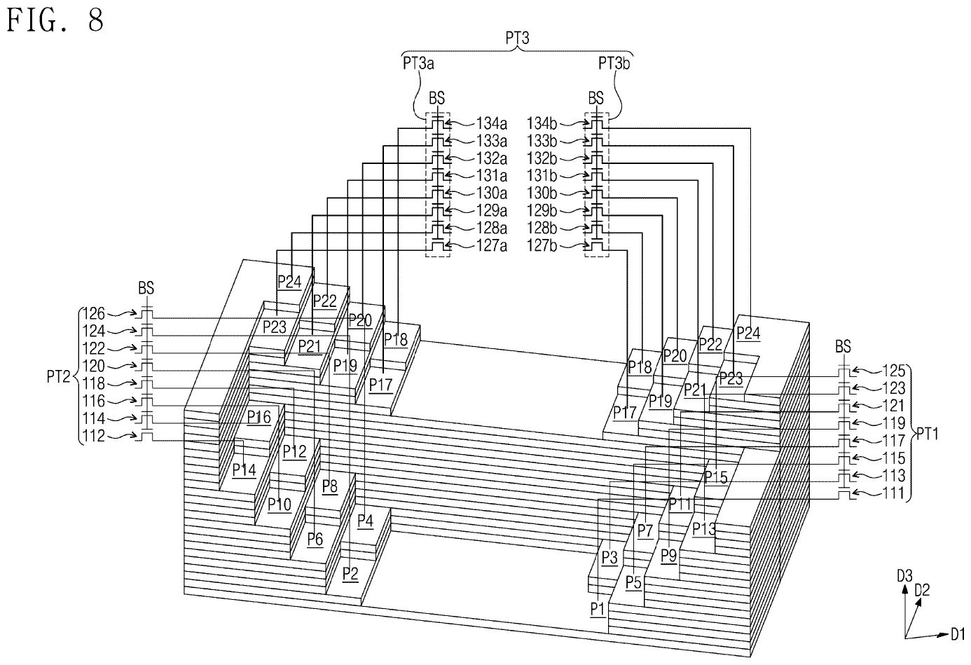

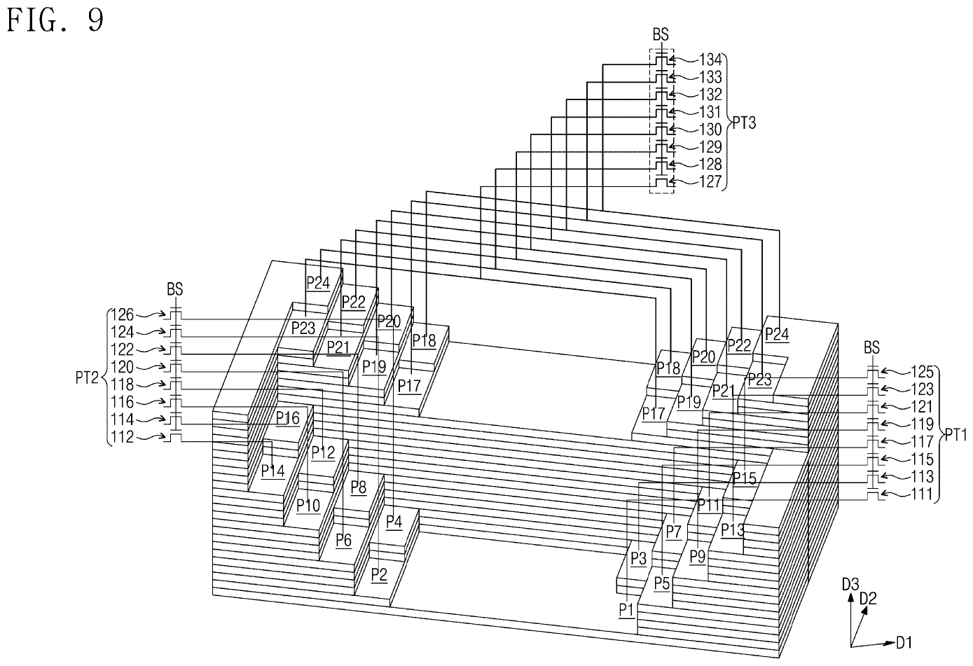

FIGS. 8 and 9 illustrate perspective views showing a connection relationship between a stack structure and pass transistors in a semiconductor device according to some embodiments of the present inventive concepts.

Referring to FIGS. 7 and 8, as discussed above, the first stack structure ST1 may include the first and second stepwise structures STR1 and STR2 that are asymmetric with each other on the lower pad region LPR, and the second stack structure ST2a and ST2b on the first stack structure ST1 may include the third and fourth stepwise structures STR3 and STR4 that are symmetric with each other on the upper pad region UPR.

In the first stack structure ST1, first pass transistors 111, 113, 115, 117, 119, 121, 123, and 125 may be correspondingly electrically coupled to the pad portions P1, P3, P5, P7, P9, P11, P13, and P15 of the odd-numbered first conductive patterns GE1, GE3, GE5, GE7, GE9, GE11, GE13, and GE15. The first pass transistors 111, 113, 115, 117, 119, 121, 123, and 125 may be controlled by the block selection signal BS.

In the second stepwise structure STR2 of the first stack structure ST1, second pass transistors 112, 114, 116, 118, 120, 122, 124, and 126 may be correspondingly electrically connected to the pad portions P2, P4, P6, P8, P10, P12, P14, and P16 of the even-numbered first conductive patterns GE2, GE4, GE6, GE8, GE10, GE12, GE14, and GE16. The second pass transistors 112, 114, 116, 118, 120, 122, 124, and 126 may be controlled by the block selection signal BS.

The second stack structure ST2a and ST2b on the first stack structure ST1 may include the first sub-stack structure ST2a and the second sub-stack structure ST2b. The second conductive patterns GE17 to GE24 of the first sub-stack structure ST2a may be connected to the first sub-pass transistor circuit PT3a, and the second conductive patterns GE17 to GE24 of the second sub-stack structure ST2b may be connected to the second sub-pass transistor circuit PT3b.

The first sub-pass transistor circuit PT3a may include first sub-pass transistors 127a to 134a (also referred to herein as first sub-transistors), and the second sub-pass transistor circuit PT3b may include second sub-pass transistors 127b to 134b (also referred to herein as second sub-transistors).

The first sub-pass transistors 127a to 134a and the second sub-pass transistors 127b to 134b may be controlled in common by the block selection signal BS.

According to some embodiments, the first sub-pass transistors 127a to 134a and the second sub-pass transistors 127b to 134b may be provided on the semiconductor substrate 10 of the upper pad region UPR discussed with reference to FIGS. 6A, 6B, 6C, and 6D.

Referring to FIGS. 7 and 9, the second conductive patterns GE17 to GE24 of the first sub-stack structure ST2a and the second sub-stack structure ST2b may be connected to corresponding third pass transistors 127 to 134. In the first sub-stack structure ST2a and the second sub-stack structure ST2b, among the second conductive patterns GE17 to GE24, ones located at the same layer (i.e., at the same vertical level) may be electrically connected in common to one of the third pass transistors 127 to 134.

According to some embodiments, the third pass transistors 127 to 134 may be provided on the semiconductor substrate 10 of the upper pad region UPR discussed with reference to FIGS. 6A, 6B, 6C, and 6D.

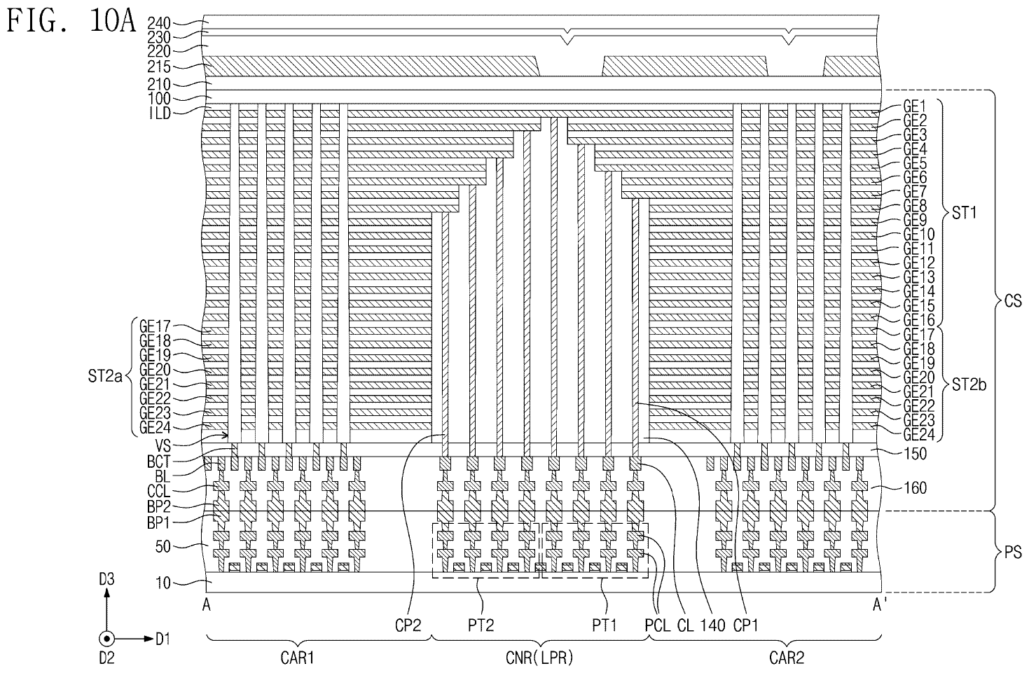

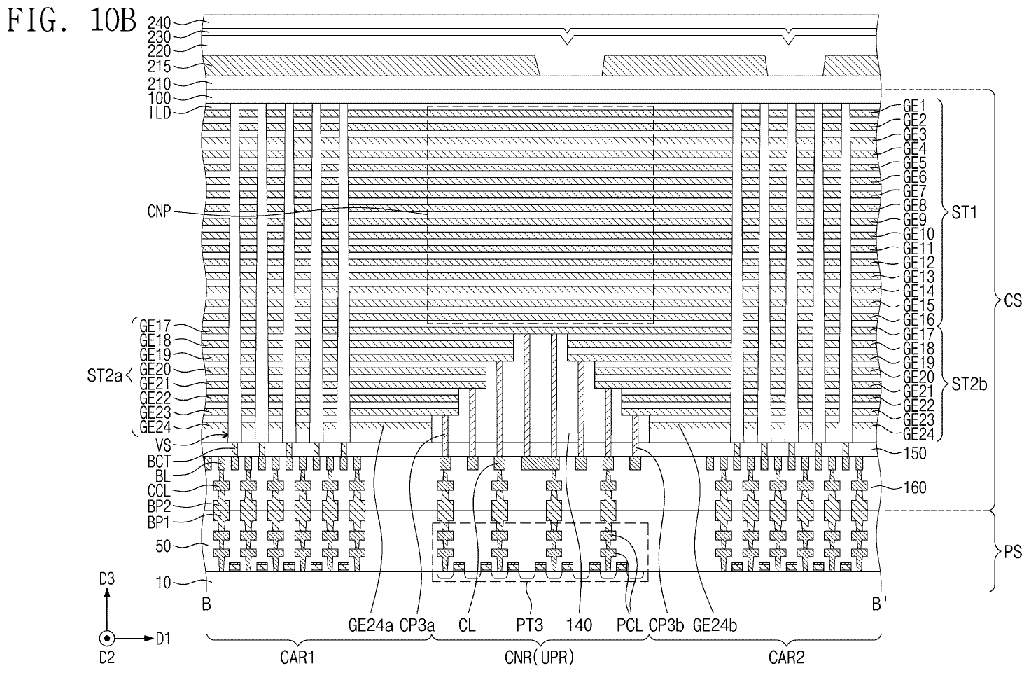

FIGS. 10A and 10B illustrate cross-sectional views respectively taken along lines A-A′ and B-B′ of FIG. 5, showing a semiconductor device according to some embodiments of the present inventive concepts. The same technical features as those of the semiconductor device discussed above may be omitted in the interest of brevity of description.

A semiconductor device according to some embodiments of the present inventive concepts may have a chip-to-chip (C2C) structure. The chip-to-chip (C2C) structure may be fabricated by forming on a first wafer a lower chip including the peripheral circuit structure PS, forming on a second wafer different from the first wafer an upper chip including the cell array structure CS, and then using a bonding method to connect the upper chip and the lower chip to each other. For example, the bonding method may include electrically connecting a bonding metal formed on an uppermost metal layer of the upper chip to a bonding metal formed on an uppermost metal layer of the lower chip. For example, when the bonding metal is formed of copper (Cu), the bonding method may be a Cu-to-Cu bonding method. The bonding metal may also be formed of, for example, aluminum (Al) or tungsten (W).

Such method, in which the peripheral circuit structure PS and the cell array structure CS are each fabricated and then combined with each other, may be employed to prevent peripheral circuits from damage due to various heat treatment processes, and thus it may be possible to improve reliability and electrical properties of a three-dimensional semiconductor device according to the present inventive concepts.

For example, referring to FIGS. 10A and 10B, the peripheral circuit structure PS may be integrated on a front surface of the semiconductor substrate 10, and may include peripheral circuits that control a memory cell array, peripheral circuit lines PCL electrically connected to the peripheral circuits, first bonding pads BP1 electrically connected to the peripheral circuit lines PCL, and a lower dielectric layer 50 that surrounds the peripheral circuits, the peripheral circuit lines PCL, and the first bonding pads BP1.

As discussed above, the peripheral circuit structure PS may include pass transistor circuits PT1, PT2, and PT3 (i.e., PT3a and PT3b) on the connection region CNR between the first and second cell array regions CAR1 and CAR2.

The first bonding pads BP1 may be disposed in an uppermost portion of the lower dielectric layer 50. The lower dielectric layer 50 may not cover top surfaces of the first bonding pads BP1. The uppermost portion of the lower dielectric layer 50 may have a top surface substantially coplanar with those of the first bonding pads BP1. The first bonding pads BP1 may be electrically connected through peripheral circuit lines PCL to the peripheral circuits.

The cell array structure CS may be provided on the peripheral circuit structure PS. The cell array structure CS may include a semiconductor layer 100, first and second stack structures ST1, ST2a, and ST2b, vertical structures VS, bit lines BL, connection lines CL, cell contact plugs CP1, CP2, CP3a, and CP3b, input/output lines 215, and second bonding pads BP2.

In the present embodiment, differently from the embodiment of FIGS. 6A to 6D, the first and second stack structures ST1, ST2a, and ST2b may have substantially the same structure as that of the first and second stack structures ST1, ST2a, and ST2b, except that the connection region CNR has an inverse stepwise structure.

The bit lines BL may be disposed on the interlayer dielectric layer 150 on the cell array regions CAR1 and CAR2, and the connection lines CL may be disposed on the interlayer dielectric layer 150 on the connection region CNR.

The bit lines BL may extend in the second direction D2, while running across the stack structure ST. The bit lines BL may be electrically connected through the bit-line contact plugs BCT to the vertical structures VS.

Cell conductive lines CCL may electrically connect the bit lines BL to the second bonding pads BP2.

On the connection region CNR, cell contact plugs CP1, CP2, CP3a, and CP3b may be correspondingly coupled to the pad portions P1 to P24 of the conductive patterns GE1 to GE24.

For example, first cell contact plugs CP1 may be in contact with corresponding odd-numbered first conductive patterns GE1, GE3, GE5, GE7, GE9, GE11, GE13, and GE15. Second cell contact plugs CP2 may be in contact with corresponding even-numbered first conductive patterns GE2, GE4, GE6, GE8, GE10, GE12, GE14, and GE16.

Third cell contact plugs CP3a and CP3b may electrically connect the second conductive patterns GE17 to GE24 to their corresponding pass transistors of the third pass transistor circuits PT3a and PT3b (i.e., PT3). Ones CP3a of the third cell contact plugs CP3a and CP3b may be correspondingly coupled to the pad portions P17 to P24 of the second conductive patterns GE17 to GE24 of the first sub-stack structure ST2a, and others CP3b of the third cell contact plugs CP3a and CP3b may be correspondingly coupled to the pad portions P17 to P24 of the second conductive patterns GE17 to GE24 of the second sub-stack structure ST2b.

On the connection region CNR, the connection lines CL may be disposed on the interlayer dielectric layer 150 and connected to the cell contact plugs CP1, CP2, CP3a, and CP3b.

According to the present embodiment, among the second conductive patterns GE17 to GE24 in the first and second sub-stack structures ST2a and ST2b, ones located at the same layer may be electrically connected in common through one connection line CL to the third cell contact plugs CP3a and CP3b.

The second bonding pads BP2 may be provided in an uppermost portion of an interlayer dielectric layer 160 of the cell array structure CS. The second bonding pads BP2 may be electrically connected to the bit lines BL and the connection lines CL. The uppermost portion of the interlayer dielectric layer 160 may have a surface in direct contact with that of the uppermost portion of the lower dielectric layer 50 of the peripheral circuit structure PS.

A bonding method may be employed to electrically and physically connect the second bonding pads BP2 to the first bonding pads BP1. For example, the second bonding pads BP2 may be in direct contact with the first bonding pads BP1. The second bonding pads BP2 may have substantially the same shape, width, and area as those of the first bonding pads BP1. The second bonding pads BP2 may include the same metallic material as that of the first bonding pads BP1. The second bonding pads BP2 may be formed of, for example, aluminum, copper, or tungsten.

A surface dielectric layer 210 may cover a backside surface of the semiconductor layer 100. The input/output lines 215 may be disposed on the surface dielectric layer 210. A capping dielectric layer 220 may be disposed on the surface dielectric layer 210, and the capping dielectric layer 220 may cover the input/output lines 215. The input/output lines 215 may be electrically connected to the cell array structure CS to the peripheral circuit structure PS.

A protection layer 230 and a passivation layer 240 may be sequentially formed on a front surface of the capping dielectric layer 220. The protection layer 230 may include, for example, a silicon nitride layer or a silicon oxynitride layer. The passivation layer 240 may include a polyimide-based material, such as photosensitive polyimide (PSPI).

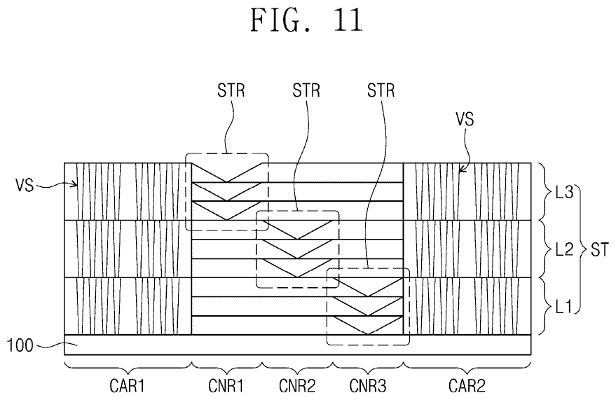

FIG. 11 illustrates a simplified cross-sectional view showing a cell array structure of a semiconductor device according to some embodiments of the present inventive concepts.

Referring to FIG. 11, a semiconductor device according to some embodiments of the present inventive concepts may include first and second cell array regions CAR1 and CAR2, and may also include first, second, and third connection regions CNR1, CNR2, and CNR3 that are arranged along one direction between the first and second cell array regions CAR1 and CAR2.

First, second, and third structures L1, L2, and L3 may be sequentially stacked on a substrate, for example, a semiconductor layer 100. Each of the first, second, and third structures L1, L2, and L3 may have a uniform thickness on the first and second cell array regions CAR1 and CAR2. The first structure L1 may have a stepwise structure STR on the third connection region CNR3, the second structure L2 may have a stepwise structure STR on the second connection region CNR2, and the third structure L3 may have a stepwise structure STR on the first connection region CNR1. The stepwise structures STR of the first, second, and third structures L1, L2, and L3 may not overlap each other.

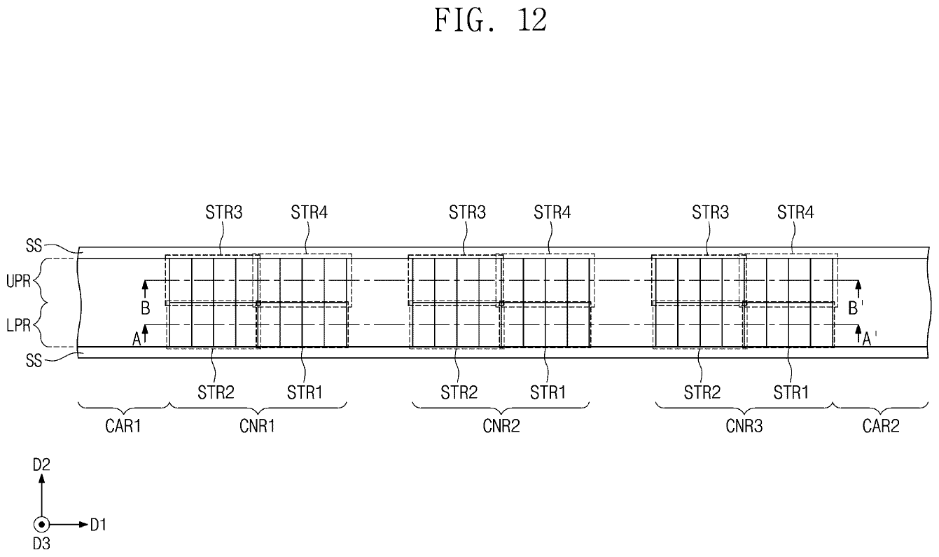

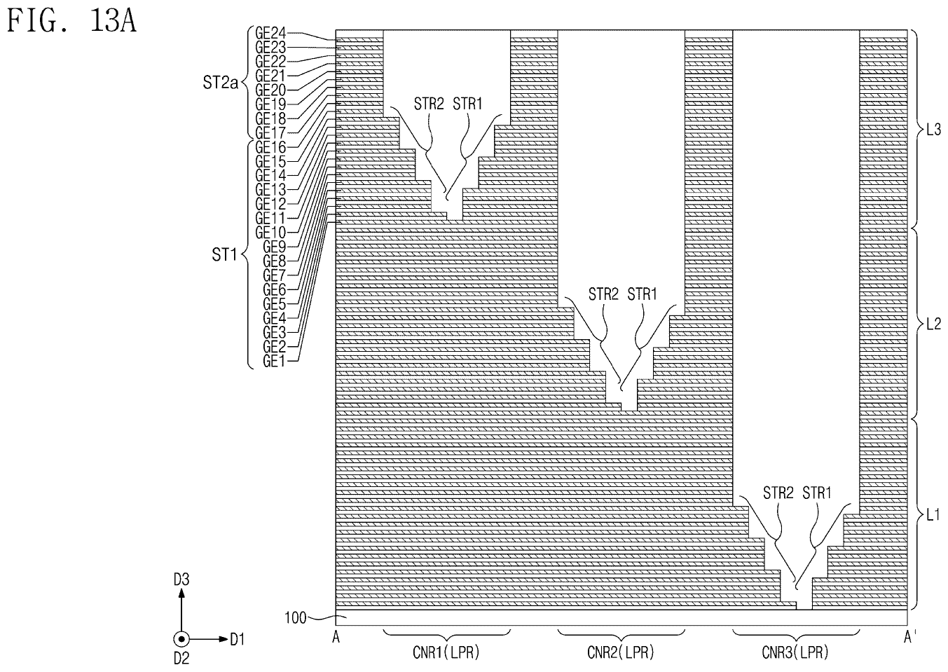

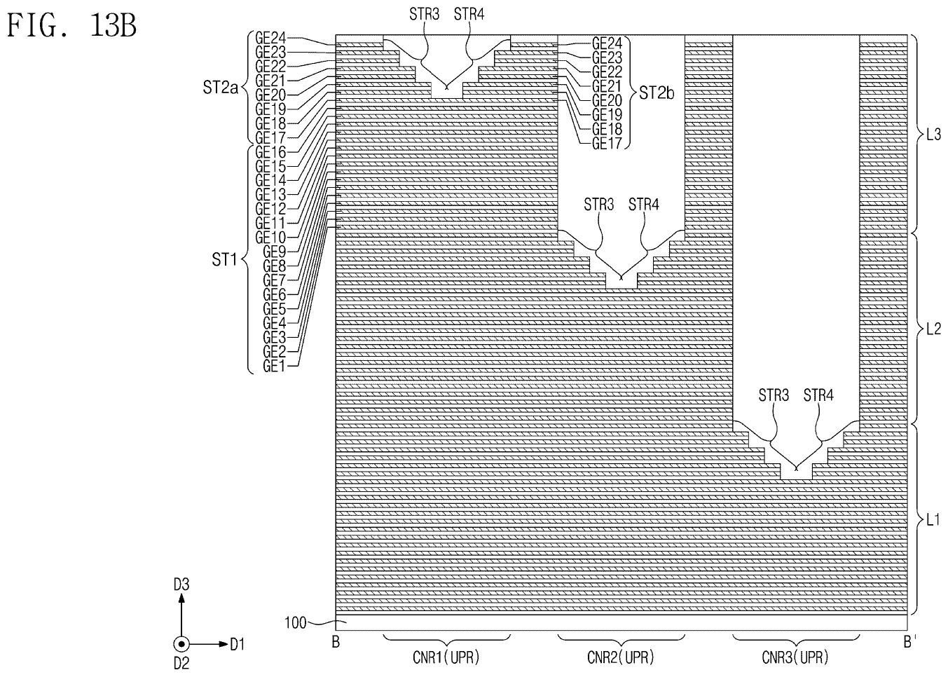

FIG. 12 illustrates a plan view partially showing a semiconductor device according to some embodiments of the present inventive concepts. FIGS. 13A and 13B illustrate cross-sectional views respectively taken along lines A-A′ and B-B′ of FIG. 12, showing a semiconductor device according to some embodiments of the present inventive concepts. The same technical features as those of the stack structure discussed above may be omitted in the interest of brevity of description.

Referring to FIGS. 12, 13A, and 13B, a semiconductor device may include first and second cell array regions CAR1 and CAR2, and may also include first, second, and third connection regions CNR1, CNR2, and CNR3 that are arranged along one direction between the first and second cell array regions CAR1 and CAR2. Each of the first, second, and third connection regions CNR1, CNR2, and CNR3 may include a lower pad region LPR and an upper pad region UPR disposed in the second direction D2 that intersects the first direction D1.

First, second, and third structures L1, L2, and L3 may be sequentially stacked on a semiconductor layer 100. The first, second, and third structures L1, L2, and L3 may extend along the first direction D1, and may have a uniform thickness on the first and second cell array regions CAR1 and CAR2.

As discussed with reference to FIG. 7, each of the first, second, and third structures L1, L2, and L3 may include a first stack structure ST1 and a second stack structure ST2a and ST2b on the first stack structure ST1.

In each of the first, second, and third structures L1, L2, and L3, the first stack structure ST1 may include a connection portion CNP that has a uniform thickness on the lower pad region LPR, and the second stack structure ST2 may include first and second sub-stack structures ST2a and ST2b that are spaced apart from each other on the connection portion CNP of the first stack structure ST1.

As discussed with reference to FIG. 7, each of the first, second, and third structures L1, L2, and L3 may include first and second stepwise structures STR1 and STR2 that are disposed asymmetrically with each other, and may also include third and fourth stepwise structures STR3 and STR4 that are disposed symmetrically with each other.

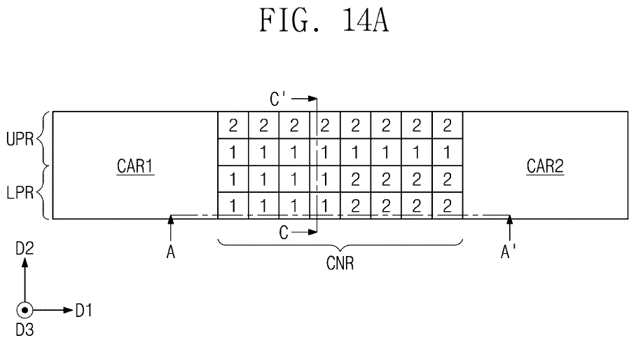

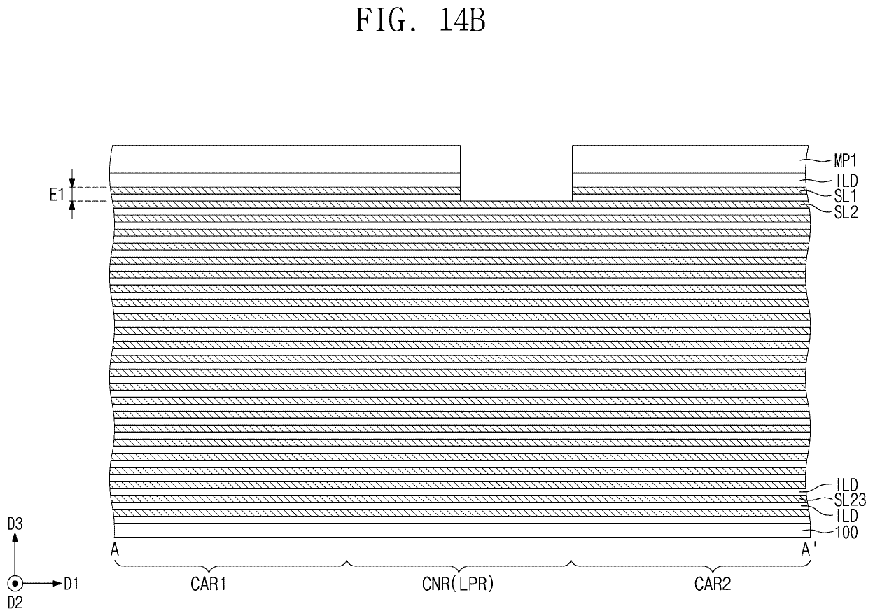

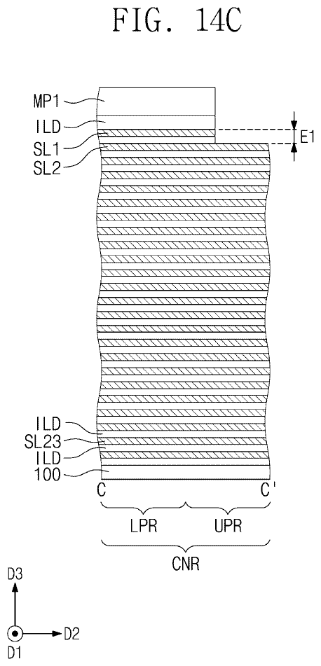

FIGS. 14A, 15A, 16A, 17A, 18A, and 19A illustrate plan views showing a method of forming a stack structure in a semiconductor device according to some embodiments of the present inventive concepts. FIGS. 14B, 15B, 16B, 17B, 18B, and 19B illustrate cross-sectional views taken along line A-A′ of FIGS. 14A, 15A, 16A, 17A, 18A, and 19A, respectively. FIGS. 14C, 15C, 16C, 17C, 18C, and 19C illustrate cross-sectional views taken along line C-C′ of FIGS. 14A, 15A, 16A, 17A, 18A, and 19A, respectively.

In FIGS. 14A, 15A, 16A, 17A, 18A, and 19A, digits on a connection region CNR indicate levels of horizontal layers and are written in ascending order from a horizontal layer furthest from a semiconductor layer 100.

Referring to FIGS. 14A, 14B, and 14C, a thin structure may be formed on a semiconductor layer 100, which thin structure includes horizontal layers SL1 to SL24 and dielectric layers ILD that are vertically alternately stacked. In some embodiments, it is illustrated that 24 horizontal layers are stacked, but the present inventive concepts are not limited thereto.

The semiconductor layer 100 may include first and second cell array regions CAR1 and CAR2, and may also include a connection region CNR that is disposed in a first direction D1 between the first and second cell array regions CAR1 and CAR2. The connection region CNR may include a lower pad region LPR and an upper pad region UPR that are adjacent to each other in a second direction D2 that intersects the first direction D1.

The horizontal layers SL1 to SL24 may be formed of a material having an etch selectivity with respect to the dielectric layers ILD. For example, the dielectric layers ILD may include a silicon oxide layer, and the horizontal layers SL1 to SL24 may include at least one selected from a silicon nitride layer, a silicon oxynitride layer, a polycrystalline silicon layer, or a metal layer. The horizontal layers SL1 to SL24 may include a semiconductor layer or a conductive layer.

A first mask pattern MP1 may be formed on an uppermost dielectric layer ILD. The first mask pattern MP1 may expose a portion of the thin structure on the connection region CNR. The first mask pattern MP1 may have an opening substantially shaped like an L or bracket.

The first mask pattern MP1 may be used as an etching mask to perform a single-layer etching process that etches a portion of the thin structure. The single-layer etching process may etch the thin structure to a first etching depth E1 that corresponds to a vertical pitch of the horizontal layers SL1 to SL24. The vertical pitch of the horizontal layers SL1 to SL24 may indicate a vertical distance between top surfaces of neighboring ones of the horizontal layers SL1 to SL24, which neighboring ones are adjacent to each other in a third direction D3.

As the single-layer etching process is performed once, an uppermost horizontal layer SL1 may be etched. Therefore, a one-step staircase may be formed in the first direction D1 on the lower pad region LPR, and a one-step staircase may be formed in the second direction D2 on the upper pad region UPR.

After the single-layer etching process is performed once, the first mask pattern MP1 may be removed.

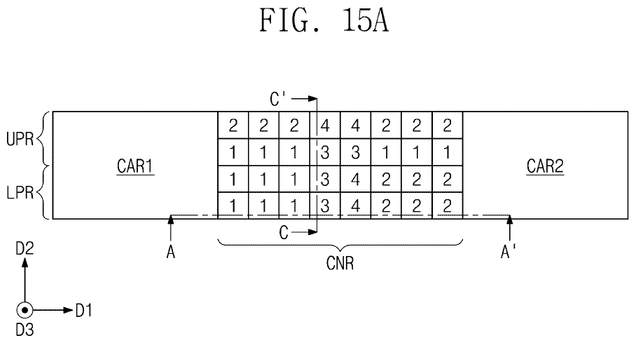

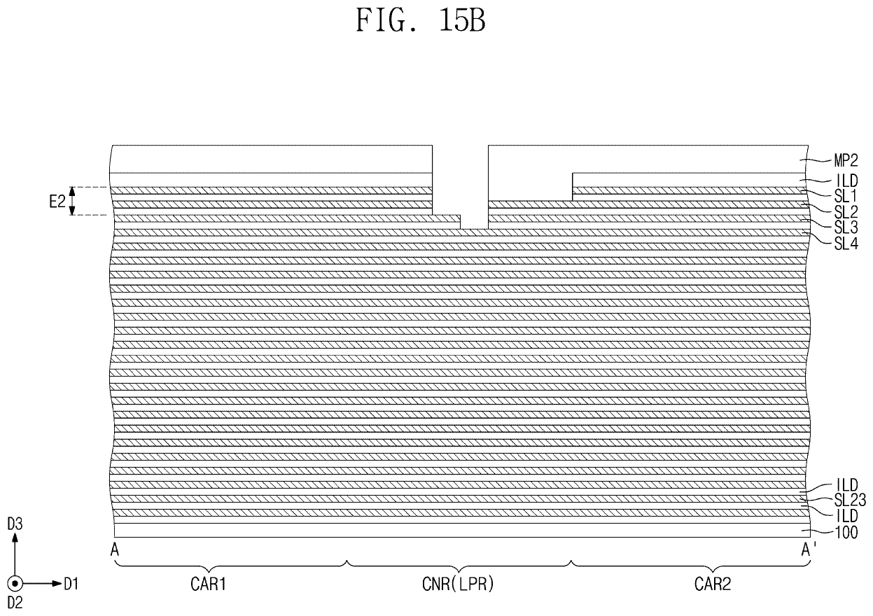

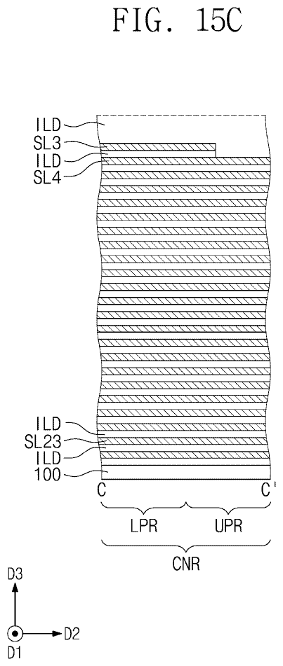

Referring to FIGS. 15A, 15B, and 15C, a second mask pattern MP2 may be formed on the uppermost dielectric layer ILD. The second mask pattern MP2 may have an opening that extends in the second direction D2 on the connection region CNR. The second mask pattern MP2 may be used as an etching mask to perform a first multi-layer etching process on a portion of the thin structure.

The first multi-layer etching process may include etching at least two of the horizontal layers SL1 to SL24. For example, the first multi-layer etching process may etch the thin structure to a second etching depth E2 that corresponds to about twice the vertical pitch of the horizontal layers SL1 to SL24. When the first multi-layer etching process is performed, a step difference formed in the first direction D1 on the lower pad region LPR may be downwardly transferred to the thin structure, and a step difference formed in the second direction D2 on the upper pad region UPR may be downwardly transferred to the thin structure.

A first trimming process may be performed to reduce an area of the second mask pattern MP2. For example, the first trimming process may increase a width in the first direction D1 of the opening in the second mask pattern MP2.

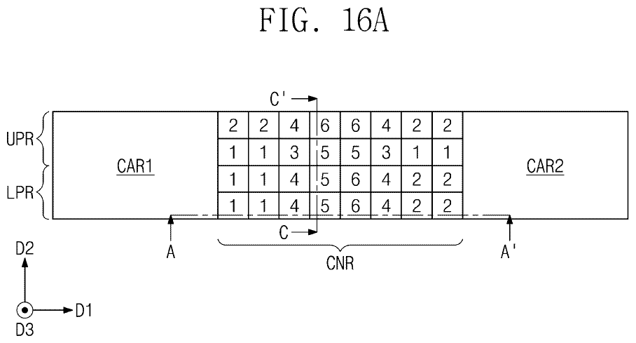

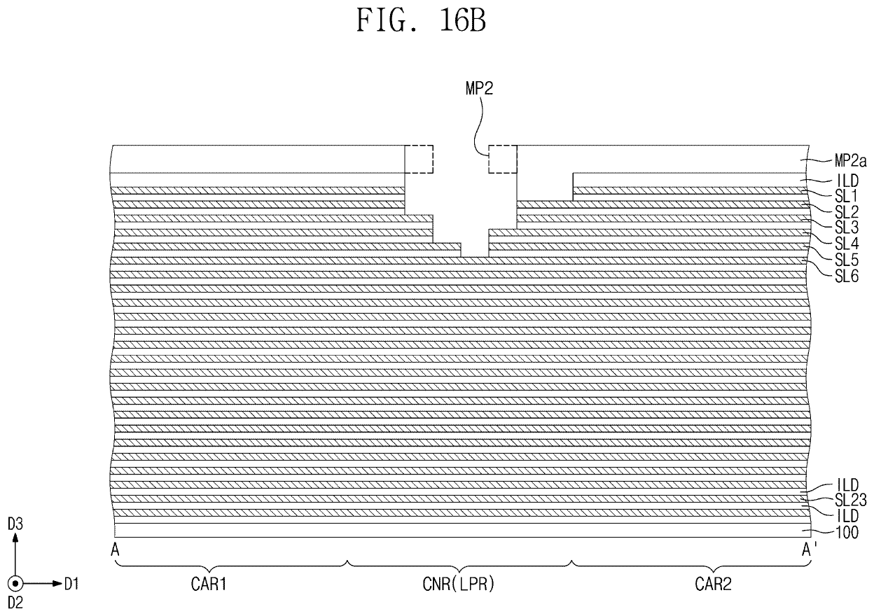

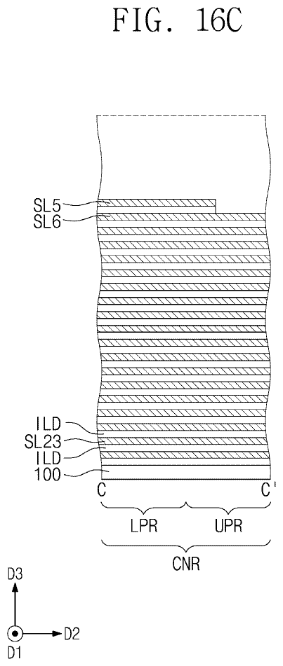

Referring to FIGS. 16A, 16B, and 16C, a trimmed second mask pattern MP2a may be used as an etching mask to perform a first multi-layer etching process on a portion of the thin structure.

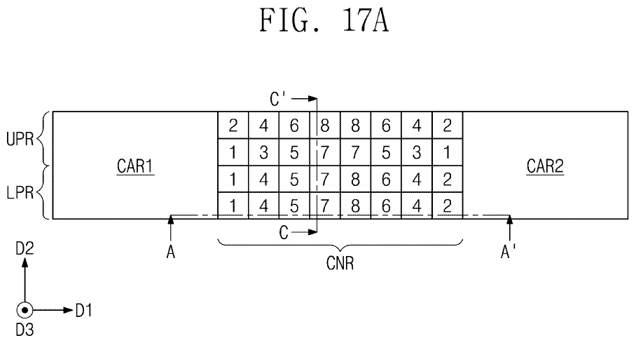

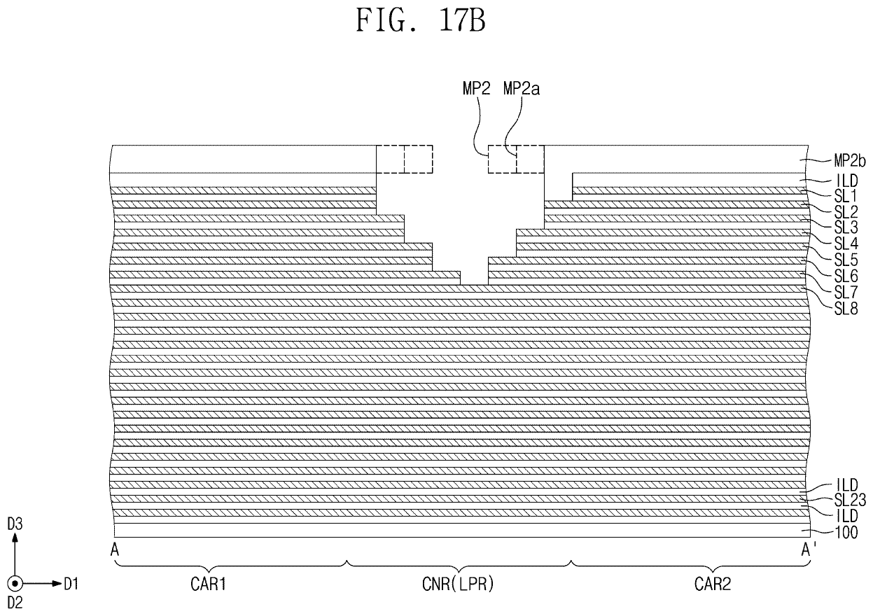

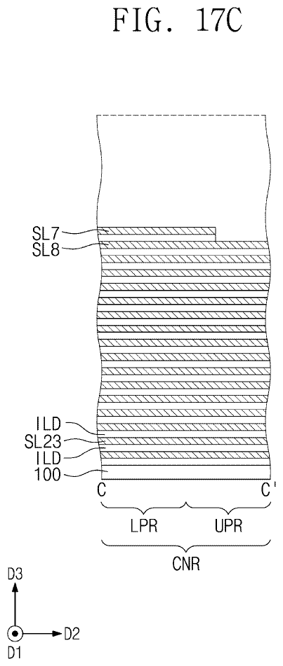

Referring to FIGS. 16A, 16B, 16C, 17A, 17B, and 17C, a trimming process on the second mask pattern MP2a or MP2b and the first multi-layer etching process may be alternately and repeatedly performed. Thus, a two-step staircase may be simultaneously formed along the first direction D1 on the lower pad region LPR and the upper pad region UPR.

According to some embodiments, while the first multi-layer etching process is performed a plurality of times, a two-step staircase may be simultaneously formed on the lower pad region LPR and the upper pad region UPR without a mask pattern that covers a portion (e.g., the upper pad region UPR) of the connection region CNR.

Accordingly, on the lower pad region LPR, first and second stepwise structures that are asymmetric with each other in the first direction D1 may be formed on an upper portion of the thin structure, and on the upper pad region UPR, stepwise structures that are symmetric with each other in the first direction D1 may be formed on an upper portion of the thin structure.

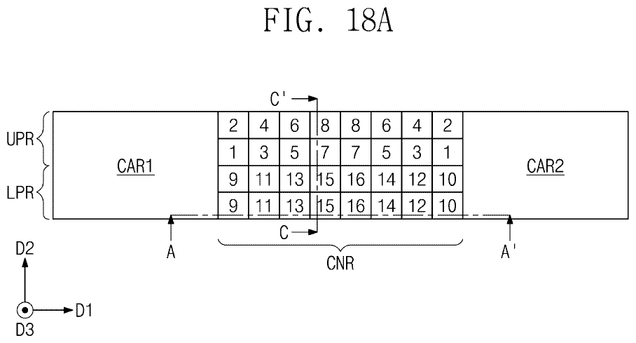

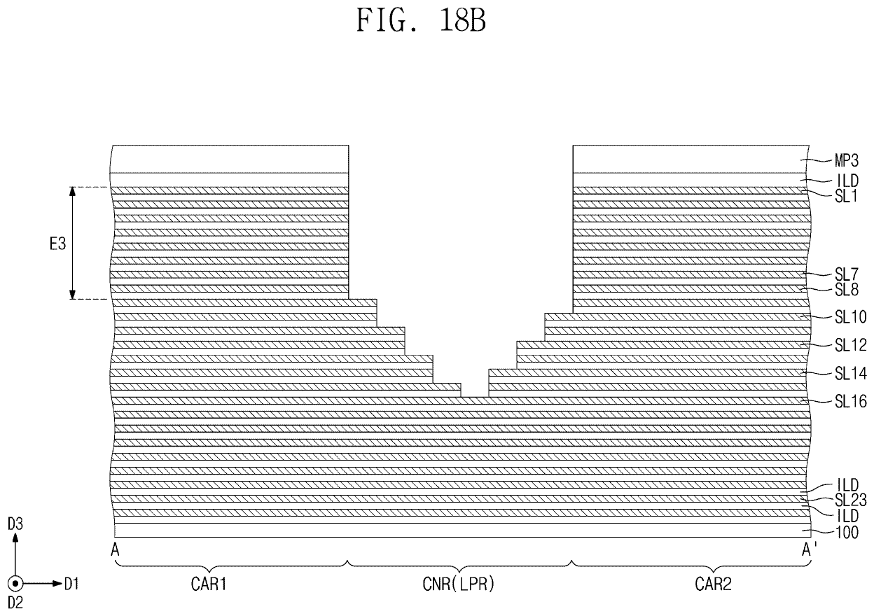

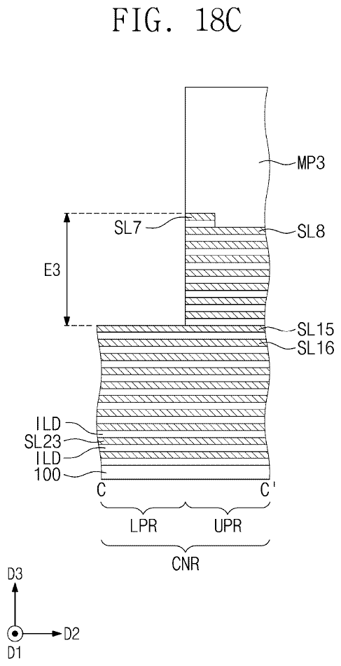

Referring to FIGS. 18A, 18B, and 18C, a third mask pattern MP3 may be formed on the thin structure, which third mask pattern MP3 has an opening that exposes the lower pad region LPR.

The third mask pattern MP3 may be used as an etching mask to perform a second multi-layer etching process on a portion of the thin structure. The second multi-layer etching process may etch the thin structure to a third etching depth E3 that corresponds to about eight times the vertical pitch of the horizontal layers SL1 to SL24. The third etching depth E3 may be greater than the second etching depth E2 of the first multi-layer etching process. In the second multi-layer etching process, an etching depth may be changed depending on the number of stacked horizontal layers SL1 to SL24.

As the second multi-layer etching process is performed, an eight-step staircase may be formed in the second direction D2 on the lower pad region LPR.

Afterwards, the third mask pattern MP3 may be removed, or a trimming process may be performed to reduce an area of the third mask pattern MP3.

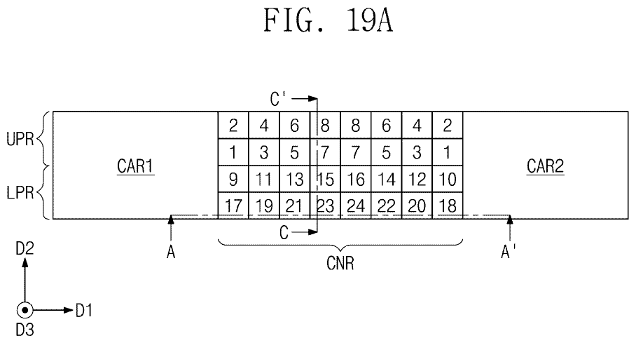

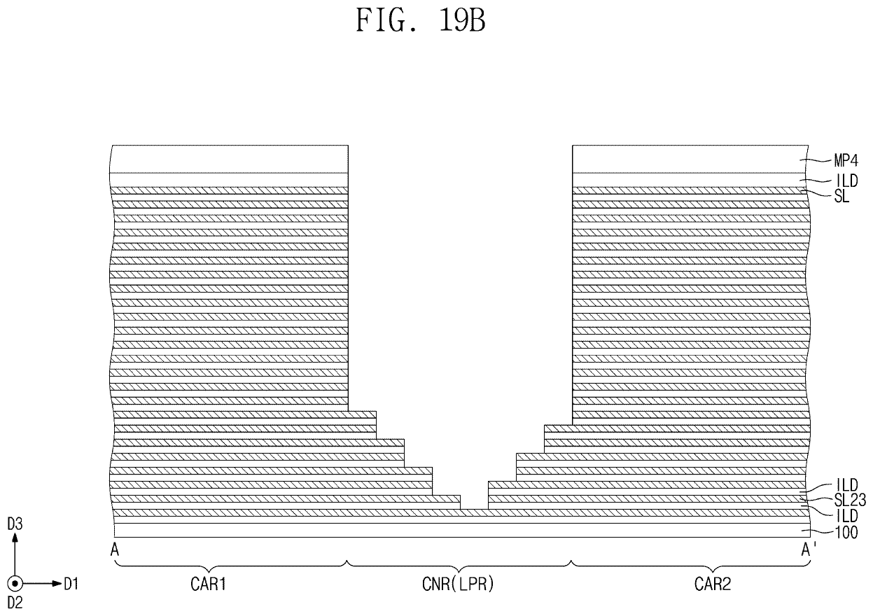

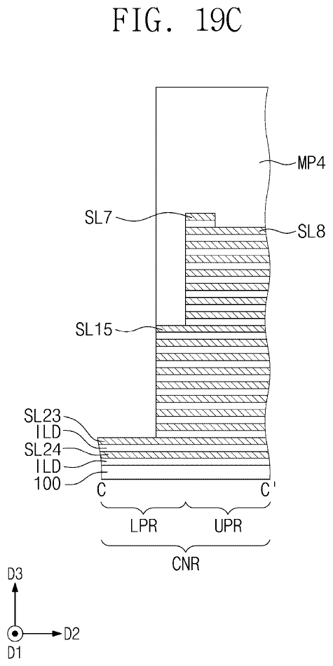

Referring to FIGS. 19A, 19B, and 19C, a fourth mask pattern MP4 may be formed to cover the upper pad region UPR and a portion of the lower pad region LPR.

The fourth mask pattern MP4 may be used as an etching mask to perform a second multi-layer etching process on a portion of the thin structure.

Therefore, on the lower pad region LPR, first and second stepwise structures that are asymmetric with each other in the first direction D1 may be formed on a lower portion of the thin structure, and on the upper pad region UPR, a lower portion of the thin structure may not be etched. For example, as the third and fourth mask patterns MP3 and MP4 are formed to cover the upper pad region UPR, portions of the horizontal layers SL16 to SL24 may not be separated on the upper pad region UPR.

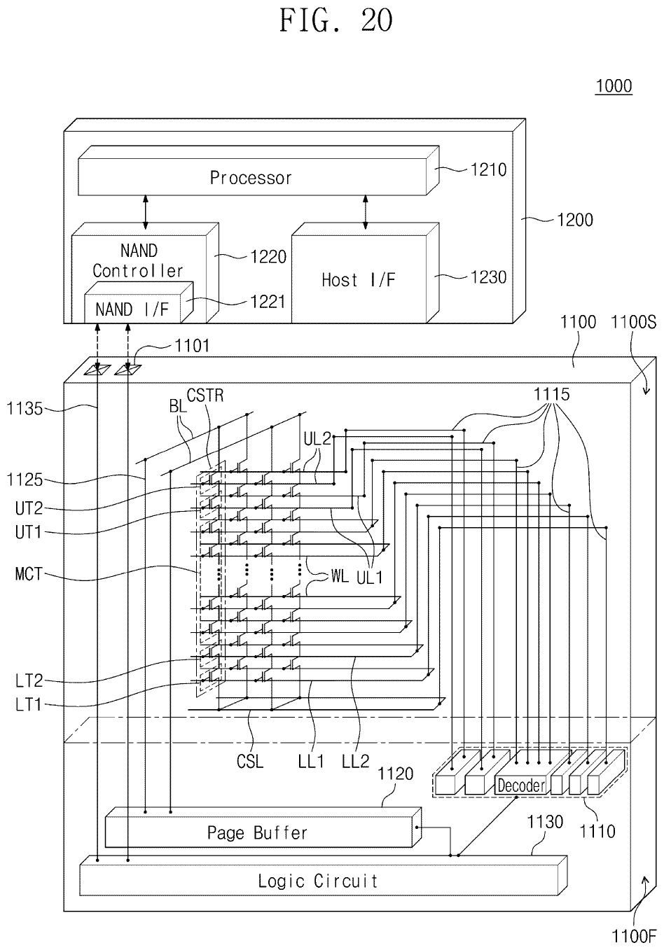

FIG. 20 illustrates a simplified schematic diagram showing an electronic system that includes a semiconductor device according to some embodiments of the present inventive concepts.

Referring to FIG. 20, an electronic system 1000 according to some embodiments of the present inventive concepts may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, the electronic system 1000 may be a solid state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. In some embodiments, the first structure 1100F may be disposed on a side of the second structure 1100S.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The memory cell transistors MCT of each memory cell string CSTR may be controlled by a back-gate line.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F toward the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

Although not shown, the first structure 1100F may include a voltage generator. The voltage generator may produce program voltages, read voltages, pass voltages, and verification voltages that are required for operating the memory cell strings CSTR. The program voltage may be relatively higher (e.g., about 20 V to about 40 V) than the read voltage, the pass voltage, and the verification voltage.

In some embodiments, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface 1230. In some embodiments, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

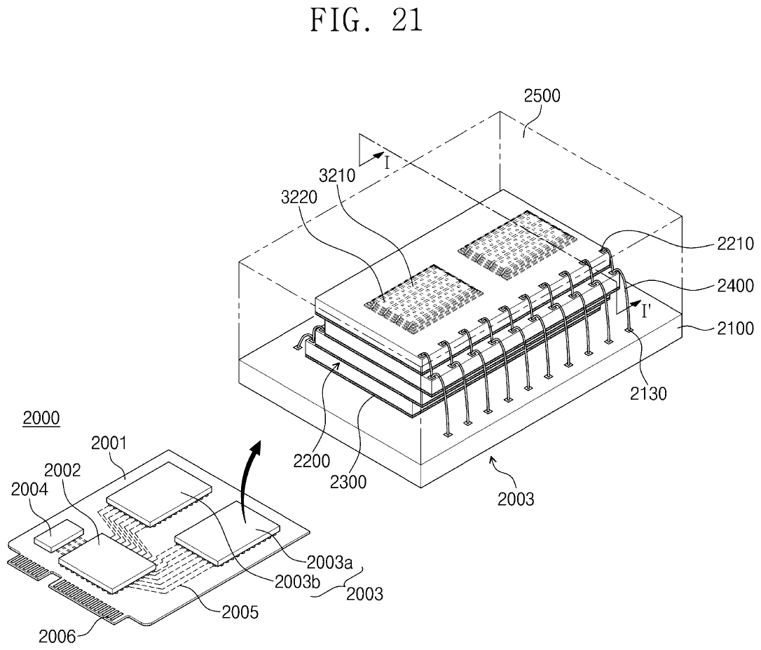

FIG. 21 illustrates a simplified perspective view showing an electronic system that includes a semiconductor device according to some embodiments of the present inventive concepts.

Referring to FIG. 21, an electronic system 2000 according to some embodiments of the present inventive concepts may include a mainboard 2001, a controller 2002 mounted on the mainboard 2001, one or more semiconductor packages 2003, and a dynamic random access memory (DRAM) 2004. The semiconductor package 2003 and the DRAM 2004 may be connected to the controller 2002 through wiring patterns 2005 formed on the mainboard 2001.

The mainboard 2001 may include a connector 2006 including a plurality of pins that are coupled to an external host. The number and arrangement of the plurality of pins in the connector 2006 may be changed based on a communication interface between the electronic system 2000 and the external host. In some embodiments, the electronic system 2000 may communicate with the external host through one or more interfaces, for example, universal serial bus (USB), peripheral component interconnect express (PCI-Express), serial advanced technology attachment (SATA), and M-PHY for universal flash storage (UFS). In some embodiments, the electronic system 2000 may operate with power supplied through the connector 2006 from the external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be a printed circuit board including upper pads 2130. Each of the semiconductor chips 2200 may include one or more input/output pads 2210. The input/output pad 2210 may correspond to the input/output pad 1101 of FIG. 20. Each of the semiconductor chips 2200 may include stack structures 3210 and vertical structures 3220. Each of the semiconductor chips 2200 may include the aforementioned semiconductor device according to some embodiments of the present inventive concepts.

In some embodiments, the connection structure 2400 may be a bonding wire that electrically connects the input/output pad 2210 to the upper pad 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. In some embodiments, in each of the first and second semiconductor packages 2003a and 2003b, the semiconductor chips 2200 may be electrically connected to each other through connection structures such as through silicon vias (TSV) instead of the connection structures 2400 shaped like bonding wires.

In some embodiments, the controller 2002 and the semiconductor chips 2200 may be included in a single package. For example, the controller 2002 and the semiconductor chips 2200 may be mounted on an interposer substrate other than the mainboard 2001, and may be connected to each other through wiring lines formed on the interposer substrate.

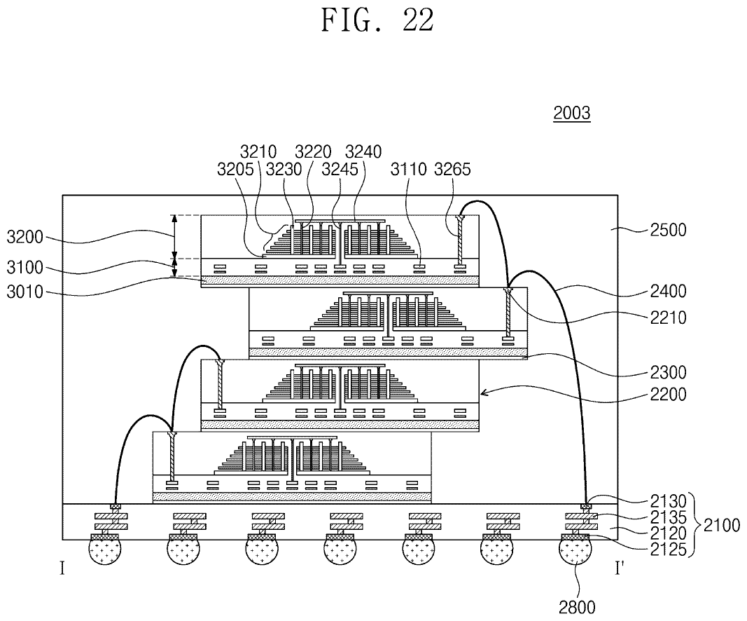

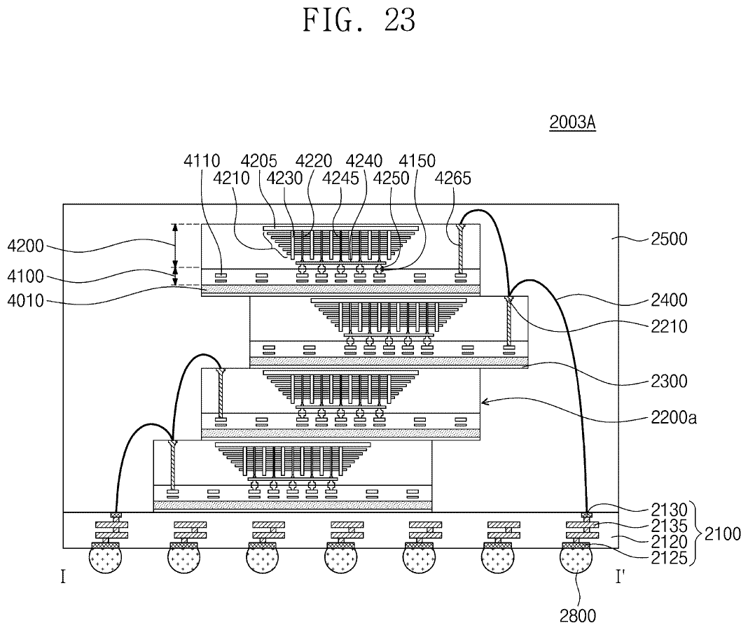

FIGS. 22 and 23 illustrate simplified cross-sectional views showing a semiconductor package according to some embodiments of the present inventive concepts. FIGS. 22 and 23 each depicts an example of the semiconductor package illustrated in FIG. 21, conceptually showing a section taken along line I-I′ of the semiconductor package illustrated in FIG. 21.

Referring to FIG. 22, in the semiconductor package 2003, the package substrate 2100 may be a printed circuit board. The package substrate 2100 may include a package substrate body 2120, upper pads 2130 (see 2130 of FIG. 21) disposed on a top surface of the package substrate body 2120, lower pads 2125 disposed or exposed on a bottom surface of the package substrate body 2120, and internal lines 2135 by which the upper pads 2130 and the lower pads 2125 are electrically connected to each other in the package substrate body 2120. The upper pads 2130 may be electrically connected to the connection structures 2400. The lower pads 2125 may be connected through conductive connectors 2800 to the wiring patterns 2005 of the mainboard 2001 in the electronic system 2000, as shown in FIG. 21.

Each of the semiconductor chips 2200 may include a semiconductor substrate 3010, and may also include a first structure 3100 and a second structure 3200 that are sequentially stacked on the semiconductor substrate 3010. The first structure 3100 may include a peripheral circuit region including peripheral wiring lines 3110. The second structure 3200 may include a source structure 3205, a stack structure 3210 on the source structure 3205, vertical structures 3220 and separation structures 3230 that penetrate the stack structure 3210, bit lines 3240 electrically connected to the vertical structures 3220, cell contact plugs electrically connected to the word lines (see WL of FIG. 20) of the stack structure 3210, and input/output interconnection lines 3265. Each of the first structure 3100, the second structure 3200, and the semiconductor chips 2200 may further include separation structures which are discussed above.

Each of the semiconductor chips 2200 may include one or more through wiring lines 3245 that extend into the second structure 3200 and are electrically connected to the peripheral wiring lines 3110 of the first structure 3100. The through wiring line 3245 may be disposed outside the stack structure 3210 and may further be disposed to penetrate the stack structure 3210. Each of the semiconductor chips 2200 may further include one or more input/output pads 2210 (see 2210 of FIG. 21) electrically connected to the peripheral wiring lines 3110 of the first structure 3100 through the input/output interconnection lines 3265.

Referring to FIG. 23, in a semiconductor package 2003A, each of semiconductor chips 2200a may include a semiconductor substrate 4010, a first structure 4100 on the semiconductor substrate 4010, a second structure 4200 on the first structure 4100 and wafer-bonded to the first structure 4100.

The first structure 4100 may include a peripheral circuit region including peripheral wiring lines 4110 and first bonding structures 4150. The second structure 4200 may include a source structure 4205, a stack structure 4210 between the source structure 4205 and the first structure 4100, vertical structures 4220 and a separation structure 4230 that penetrate the stack structure 4210, and second bonding structures 4250 electrically connected to the vertical structures 4220 and word lines (see WL of FIG. 20) of the stack structure 4210. For example, the second bonding structures 4250 may be electrically connected to the vertical structures 4220 through bit lines 4240 electrically connected to the vertical structures 4220, and may also be electrically connected to the word lines (see WL of FIG. 20) through cell contact plugs electrically connected to the word lines (see WL of FIG. 20). The first bonding structures 4150 of the first structure 4100 and the second bonding structures 4250 of the second structure 4200 may be bonded to each other while being in contact with each other. The first and second bonding structures 4150 and 4250 may have their bonding portions formed of, for example, copper (Cu).

Each of the first structure 4100, the second structure 4200, and the semiconductor chip 2200a may further include a source structure. Each of the semiconductor chips 2200a may further include one or more input/output pads 2210 (see 2210 of FIG. 21) electrically connected to the peripheral wiring lines 4110 of the first structure 4100 through input/output interconnection lines 4265.

The semiconductor chips 2200 of FIG. 22 may be electrically connected to each other through the connection structures 2400 shaped like bonding wires, and this may also be applicable to the semiconductor chips 2200a of FIG. 23. In some embodiments, semiconductor chips, such as the semiconductor chips 2200 of FIG. 22 or the semiconductor chips 2200a of FIG. 23, in a single semiconductor package may be electrically connected to each other through one or more connection structures including through silicon vias (TSVs).

According to some embodiments of the present inventive concepts, a stepwise structure of a stack structure may be formed without forming a hardmask pattern that covers a partial region for connection between conductive patterns located at the same level in a semiconductor fabrication process. Accordingly, a semiconductor device having reduced manufacturing costs may be provided.

In addition, as conductive patterns at each level are formed of a single layer without being separated from each other in a first stack structure, there may be a reduction in the number of wiring lines connected to the conductive patterns.

Although the present inventive concepts have been described in connection with example embodiments of the present inventive concepts illustrated in the accompanying drawings, it will be understood to those skilled in the art that various changes and modifications may be made without departing from the technical spirit and essential features of the present inventive concepts. It will be apparent to those skilled in the art that various substitution, modifications, and changes may be thereto without departing from the scope of the present inventive concepts.

It will be understood that the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

What is claimed is:

1. A semiconductor device, comprising:
a semiconductor substrate that includes a first cell array region, a second cell array region, and a connection region between the first and second cell array regions, wherein the first and second cell array regions and the connection region are arranged in a first direction, and wherein the connection region includes a lower pad region and an upper pad region that are arranged in a second direction intersecting the first direction;
a peripheral circuit structure that includes peripheral circuits on the semiconductor substrate; and
a cell array structure on the peripheral circuit structure, wherein the cell array structure includes a first stack structure comprising a plurality of first conductive patterns stacked on the peripheral circuit structure and a second stack structure comprising a plurality of second conductive patterns stacked on the first stack structure,
wherein the first stack structure includes:
a connection portion that has a uniform thickness on the upper pad region; and
first and second stepwise structures that are asymmetric with each other in the first direction on the lower pad region, and
wherein the second stack structure includes third and fourth stepwise structures that are symmetric with each other in the first direction on the connection portion of the first stack structure.

2. The semiconductor device of claim 1, further comprising:
a plurality of first pass transistors and second pass transistors on the lower pad region; and
a plurality of third pass transistors on the upper pad region,
wherein the plurality of first pass transistors overlap the first stepwise structure,
wherein the plurality of second pass transistors overlap the second stepwise structure, and
wherein the plurality of third pass transistors overlap the third and fourth stepwise structures.

3. The semiconductor device of claim 2, further comprising:
a plurality of first through plugs that extend into the first stepwise structure of the first stack structure, wherein the plurality of first through plugs electrically connect first ones of the plurality of first conductive patterns to the plurality of first pass transistors, respectively;
a plurality of second through plugs that extend into the second stepwise structure of the first stack structure, wherein the plurality of second through plugs electrically connect second ones of the plurality of first conductive patterns to the plurality of second pass transistors, respectively; and
a plurality of third through plugs that extend into the third and fourth stepwise structures of the second stack structure, wherein the plurality of third through plugs electrically connect the plurality of second conductive patterns to the plurality of third pass transistors, respectively.

4. The semiconductor device of claim 3, wherein the plurality of third through plugs extend into the connection portion of the first stack structure.

5. The semiconductor device of claim 1, wherein the first stepwise structure is defined by pad portions of first ones of the plurality of first conductive patterns, and
wherein the second stepwise structure is defined by pad portions of second ones of the plurality of first conductive patterns.

6. The semiconductor device of claim 5, wherein, in each of the first and second stepwise structures, a step difference between adjacent ones of the pad portions in the first direction is different from a step difference between adjacent ones of the pad portions in the second direction.

7. The semiconductor device of claim 1, wherein each of the second conductive patterns includes first and second sub-conductive patterns that are spaced apart from each other in the first direction,
wherein the third stepwise structure is defined by pad portions of the first sub-conductive patterns, and
wherein the fourth stepwise structure is defined by pad portions of the second sub-conductive patterns.

8. The semiconductor device of claim 7, further comprising:
a plurality of first sub-transistors that are electrically connected to the pad portions of the first sub-conductive patterns, respectively; and
a plurality of second sub-transistors that are electrically connected to the pad portions of the second sub-conductive patterns, respectively.

9. The semiconductor device of claim 1, wherein a number of the second conductive patterns in the second stack structure is less than a number of the first conductive patterns in the first stack structure.

10. The semiconductor device of claim 1, wherein a step difference between steps in the first direction in each of the first and second stepwise structures is different from a step difference between steps in the first direction in each of the third and fourth stepwise structures.

11. The semiconductor device of claim 1, further comprising:
a plurality of first pass transistors that are electrically connected to first ones of the first conductive patterns, respectively;
a plurality of second pass transistors that are electrically connected to second ones of the first conductive patterns, respectively; and
a plurality of third pass transistors that are electrically connected to the second conductive patterns, respectively,
wherein the second conductive patterns include first sub-patterns that provide the third stepwise structure and second sub-patterns that provide the fourth stepwise structure, and
wherein each of the third pass transistors is electrically connected in common to ones of the first and second sub-patterns that are at a same height from the semiconductor substrate.

12. The semiconductor device of claim 1, wherein the peripheral circuit structure includes first bonding pads electrically connected to the peripheral circuits, and
wherein the cell array structure includes second bonding pads that are bonded to the first bonding pads.

13. A semiconductor device, comprising:
a semiconductor substrate that includes a first cell array region, a second cell array region, and a connection region between the first and second cell array regions, wherein the first and second cell array regions and the connection region are arranged in a first direction, and wherein the connection region includes a lower pad region and an upper pad region that are arranged in a second direction intersecting the first direction;
a peripheral circuit structure that includes pass transistors on the semiconductor substrate; and
a cell array structure on the peripheral circuit structure, wherein the cell array structure includes:
a first stack structure comprising a plurality of first conductive patterns stacked on a semiconductor layer, wherein the first stack structure includes a connection portion that has a uniform thickness on the upper pad region and first and second stepwise structures that are asymmetric with each other in the first direction on the lower pad region; and
a second stack structure comprising a plurality of second conductive patterns stacked on the first stack structure, wherein the second stack structure includes third and fourth stepwise structures that are symmetric with each other in the first direction on the connection portion of the first stack structure,
wherein the pass transistors of the peripheral circuit structure include:
first pass transistors that overlap the first stepwise structure of the first stack structure on the lower pad region;
second pass transistors that overlap the second stepwise structure of the first stack structure on the lower pad region; and
third pass transistors that overlap the third and fourth stepwise structures of the second stack structure on the upper pad region.

14. The semiconductor device of claim 13, further comprising:
a plurality of first through plugs that extend into the first stepwise structure of the first stack structure and are electrically connected to the first pass transistors, respectively;
a plurality of second through plugs that extend into the second stepwise structure of the first stack structure and are electrically connected to the second pass transistors, respectively; and
a plurality of third through plugs that extend into the third and fourth stepwise structures of the second stack structure and the connection portion of the first stack structure, wherein the plurality of third through plugs are electrically connected to the third pass transistors, respectively.

15. The semiconductor device of claim 13, wherein the first stepwise structure is defined by pad portions of first ones of the first conductive patterns, and
wherein the second stepwise structure is defined by pad portions of second ones of the first conductive patterns.

16. The semiconductor device of claim 13, wherein each of the third and fourth stepwise structures includes:
a first portion that is defined along the first direction by pad portions of first ones of the second conductive patterns; and
a second portion that is defined along the first direction by pad portions of second ones of the second conductive patterns,
wherein the first and second portions are adjacent to each other in the second direction.

17. An electronic system, comprising:
a semiconductor device; and
a controller electrically connected through an input/output pad to the semiconductor device, the controller configured to control the semiconductor device,
wherein the semiconductor device includes:
a substrate that includes first and second cell array regions and a connection region between the first and second cell array regions;
a first stack structure that comprises a plurality of first conductive patterns stacked on the substrate; and
a second stack structure that comprises a plurality of second conductive patterns stacked on the first stack structure, wherein the first and second cell array regions and the connection region are arranged in a first direction, and wherein the connection region includes a lower pad region and an upper pad region that are arranged in a second direction intersecting the first direction,
wherein the first stack structure includes:
a connection portion that has a uniform thickness on the upper pad region; and
first and second stepwise structures that are asymmetric with each other in the first direction on the lower pad region, and
wherein the second stack structure includes third and fourth stepwise structures that are symmetric with each other in the first direction on the connection portion of the first stack structure.

18. The electronic system of claim 17, further comprising:
a plurality of first pass transistors that are electrically connected to first ones of the first conductive patterns, respectively;
a plurality of second pass transistors that are electrically connected to second ones of the first conductive patterns, respectively; and
a plurality of third pass transistors that are electrically connected to the second conductive patterns, respectively,
wherein, in a plan view, the first and second pass transistors overlap the lower pad region, and
wherein, in the plan view, the third pass transistors overlap the upper pad region.

19. The electronic system of claim 18, further comprising:
a plurality of first through plugs that extend into the first stepwise structure of the first stack structure and are electrically connected to the first pass transistors, respectively;
a plurality of second through plugs that extend into the second stepwise structure of the first stack structure and are electrically connected to the second pass transistors, respectively; and
a plurality of third through plugs that extend into the third and fourth stepwise structures of the second stack structure and the connection portion of the first stack structure, wherein the plurality of third through plugs are electrically connected to the third pass transistors, respectively.

20. The electronic system of claim 17, wherein the first stepwise structure is defined by pad portions of first ones of the first conductive patterns,
wherein the second stepwise structure is defined by pad portions of second ones of the first conductive patterns, and
wherein the first ones of the first conductive patterns are alternately stacked with the second ones of the first conductive patterns.
